(19) United States
(12) Patent Application Publication
(10) Pub. No.: US 2024/0126167 A1
(43) Pub. Date: Apr. 18, 2024

(54) RADIATION-SENSITIVE COMPOSITION AND METHOD OF FORMING RESIST PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/270,256

(22) PCT Filed: Nov. 15, 2021
(86) PCT No.: PCT/JP2021/041884

§ 371 Date: Jun. 29, 2023

(30) Foreign Application Priority Data
Jan. 8, 2021 (JP) 2021-001955

(51) Int. Cl. G03F 7/004; G03F 7/038; G03F 7/039

(52) U.S. Cl. CPC G03F 7/0045; G03F 7/038; G03F 7/039

(57) ABSTRACT

A radiation-sensitive composition includes: a polymer (A) including a structural unit represented by formula (i); and an acid-generating compound including a radiation-sensitive onium cation and an organic anion (provided that the polymer (A) is excluded), while satisfying at least one of requirements [K1] and [K2]. In [K1], the polymer (A) includes a radiation-sensitive onium cation [X] including two or more of substituents β each of which is at least one type selected from the group consisting of a fluoroalkyl group and a fluoro group (provided that the fluoro group in the fluoroalkyl group is excluded). In [K2], the acid-generating compound includes a compound including a radiation-sensitive onium cation [X].

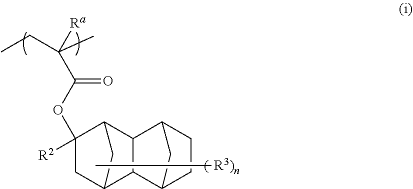

### CROSS REFERENCE TO RELATED APPLICATION

This application claims priority to Japanese Patent Application No. 2021-1955 filed on Jan. 8, 2021, the contents of which are incorporated herein by reference.

The present disclosure relates to a radiation-sensitive composition and a method of forming a resist pattern.

### BACKGROUND ART

In a lithography technology that is used in manufacturing processes of various electronic devices such as a semiconductor device and a liquid crystal device, a resist pattern is formed on a substrate by irradiating a radiation-sensitive composition with a far-ultraviolet ray such as an ArF excimer laser, an extreme ultraviolet ray (EUV), an electron beam or the like to generate an acid in an exposed portion, and causing a difference in a dissolution rate in a developer between the exposed portion and the unexposed portion, due to a chemical reaction involving the generated acid.

Further miniaturization has been rapidly advanced in various electronic device structures. Accordingly, there are demands for further miniaturization of a resist pattern in the lithography process. In response to such demands, various studies have been made to improve the resolution of chemical amplification-type radiation-sensitive compositions used in microfabrication by lithography and the rectangularity of resist patterns (see, for example, Patent Literature 1). Patent Literature 1 discloses a chemical amplification-type resist composition that contains an acid generator that contains a triarylsulfonium cation having one or more fluorine atoms and a resin that has a repeating unit having a phenolic hydroxyl group.

### CITATION LIST

### Patent Literature

Patent Literature 1: Japanese Laid-Open Patent Publication No. 2014-2359

### SUMMARY OF INVENTION

### Technical Problem

In recent years, further miniaturization of resist patterns has been rapidly advanced, for example, formation of patterns including lines with widths of 40 nm or less has been under testing. Even for forming such a fine lines in a resist pattern, formation of a proper resist pattern with a small exposure amount (i.e., with high sensitivity) is still required.

Furthermore, a radiation-sensitive composition that is used in the lithography process requires characteristics such that: CDU (Critical Dimension Uniformity) is small in hole pattern formation; and the difference in rate of dissolution in the developer is sufficiently large between the exposed portions and the unexposed portions and the amount of development residues is small.

The present disclosure has been made in view of the problems described above. An object of the present disclosure is to provide a radiation-sensitive composition and a method of forming a resist pattern capable of forming a resist pattern with high sensitivity, small CDU, and reduced development defects.

### Solution to Problem

According to the present disclosure, the following means are provided.

[1] A radiation-sensitive composition includes: a polymer (A) including a structural unit represented by formula (i); and an acid-generating compound including a radiation-sensitive onium cation structure and an organic anion structure (provided that the polymer (A) is excluded), while satisfying at least one of the following requirements [K1] and [K2];

[K1] in which the polymer (A) includes a radiation-sensitive onium cation structure [X] including two or more of substituents β each of which is at least one type selected from the group consisting of a fluoroalkyl group and a fluoro group (provided that the fluoro group in the fluoroalkyl group is excluded); and

[K2] in which the acid-generating compound includes a compound including the radiation-sensitive onium cation structure [X],

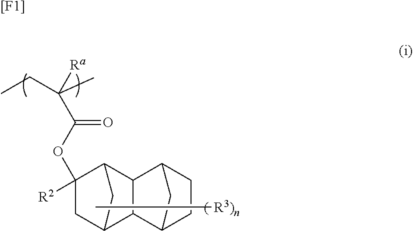

(In formula (i), R^{a} is a hydrogen atom, a fluoro group, a methyl group or a trifluoromethyl group; R² is a monovalent hydrocarbon group having 1 to 20 carbon atoms; n is an integer of 0 to 16; when n is 1, R³ is a monovalent hydrocarbon group having 1 to 20 carbon atoms; and when n is 2 or more, a plurality of R³ each independently represent a monovalent hydrocarbon group having 1 to 20 carbon atoms, or a plurality of R³ taken together represent an alicyclic structure having 3 to 20 ring members together with a carbon atom or a carbon chain to which the plurality of R³ bond.)

[2] A method of forming a resist pattern includes: forming a resist film on a substrate with use of the radiation-sensitive composition in above [1]; exposing the resist film; and developing the exposed resist film.

### Advantageous Effects of Invention

According to the radiation-sensitive composition and the method of forming the resist pattern in the present disclosure, an excellent resist pattern can be formed with a small amount of exposure because the sensitivity is high. Further, a resist pattern can be provided with small CDU and reduced developing defects.

### DESCRIPTION OF EMBODIMENTS

<<Radiation-Sensitive Composition>>

A radiation-sensitive composition of the present disclosure (hereinafter also referred to as “the present composition”) is a polymer composition that includes: a polymer (A) including a structural unit represented by formula (i) (hereinafter also referred to as “structural unit (I)”); and an acid-generating compound having a radiation-sensitive onium cation and an organic anion (provided that the polymer (A) is excluded). The composition satisfies at least one of the following requirements [K1] and [K2].

[K1] The polymer (A) includes a radiation-sensitive onium cation structure [X] having two or more of substituents β each of which is at least one type selected from the group consisting of a fluoroalkyl group and a fluoro group (provided that the fluoro group in the fluoroalkyl group is excluded) (hereinafter also referred to as “specific cation structure [X]”).

[K2] The acid-generating compound includes a compound having the specific cation structure [X].

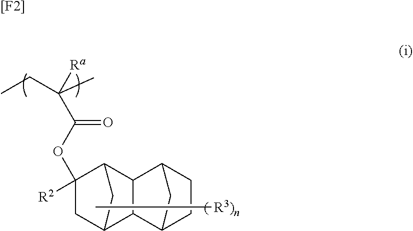

(In formula (i), R^{a} is a hydrogen atom, a fluoro group, a methyl group or a trifluoromethyl group; R² is a monovalent hydrocarbon group having 1 to 20 carbon atoms; n is an integer of 0 to 16; when n is 1, R³ is a monovalent hydrocarbon group having 1 to 20 carbon atoms; and when n is 2 or more, a plurality of R³ each independently represent a monovalent hydrocarbon group having 1 to 20 carbon atoms, or a plurality of R³ taken together represent an alicyclic structure having 3 to 20 ring members together with a carbon atom or a carbon chain to which the plurality of R³ bond.)

The acid-generating compound contained in the composition is typically a compound having a structure derived from an onium salt which has a radiation-sensitive onium cation structure and an organic anion structure (hereinafter, also simply referred to as an organic anion structure), which is a conjugate base of an acid, as a structure for generating an acid. The organic anion is usually an anion that is obtained by removing a proton from an acid group of the organic acid. In the acid-generating compound, the radiation-sensitive onium cation is decomposed by an action of radioactive rays to liberate the organic anion is bonded to hydrogen extracted from a component (for example, an acid-generating compound itself or a solvent) in the composition to give an acid to a component contained in the composition. Examples of the acid-generating compound contained in the composition include an acid generator (B) and an acid diffusion controller (C). The acid-generating compound contained in the composition may be one type or two or more types.

The polymer contained in the composition is classified as “polymer (A)” as long as the polymer has the structural unit (I). Accordingly, when the polymer in the composition has a radiation-sensitive onium cation structure and an organic anion structure together with the structural unit (I), the polymer corresponds to the “polymer (A)”. In other words, in the present specification, the “acid-generating compound” is distinguished from the polymer (A) in such a point as not to have the structural unit (I).

The specific cation structure [X] may be included in the polymer (A) or may be included in the acid-generating compound. Alternatively, both the polymer (A) and the acid-generating compound may have the specific cation structure [X]. When the acid-generating compound has the specific cation structure [X], the acid generator (B) may have the specific cation structure [X] or the acid diffusion controller (C) may have the specific cation structure [X]. A component having the specific cation structure [X] may be only one type, or two or more types. In other words, only one type among the components contained in the composition may have the specific cation structure [X], or two or more types (for example, the polymer (A) and the acid generator (B)) may have the specific cation structure [X].

The specific cation structure [X] may be a radiation-sensitive onium cation included in the polymer, or a radiation-sensitive onium cation included in a compound different from the polymer (specifically, a low-molecular-weight compound). The specific cation structure [X] may constitute at least a part of a radiation-sensitive onium cation in both the polymer and the low-molecular-weight compound. When the acid-generating compound has the specific cation structure [X], the acid-generating compound having the specific cation structure [X] may be a polymer that does not have the structural unit (I) or may be a low-molecular-weight compound. In the present specification, the “low-molecular-weight compound” refers to a compound different from a polymer, that is, a compound that does not have a repeating unit.

In the composition including the structural unit (I) and the specific cation structure [X], examples of the specific aspects of the composition satisfying at least one of the requirements [K1] and [K2] include the following aspects <1> to <3>. According to the aspects of <1> to <3>, a radiation-sensitive composition can be provided with excellent sensitivity and CDU performance and the amount of development residues is sufficiently small and thus aspects <1> to <3> are preferable.

<1> An aspect including the polymer (A), the acid generator (B) and a solvent (D). The acid generator (B) includes an onium salt having the specific cation structure [X] and an organic anion structure.

<2> An aspect including the polymer (A), the acid generator (B) and a solvent (D). The polymer (A) includes: a structural unit having a radiation-sensitive onium cation structure and an organic anion structure (hereinafter also referred to as “structural unit (IV)”) together with the structural unit (I), and the structural unit (IV) is a structural unit derived from a monomer having the specific cation structure [X] and the organic anion structure.

<3> An aspect including the polymer (A), the acid diffusion controller (C) and a solvent (D). The acid diffusion controller (C) includes an onium salt having the specific cation structure [X] and an organic anion structure.

In the aspects of <1> to <3>, other components than the components shown in each aspect may be further contained. For example, in the aspects of <1> to <3>, another component having the specific cation structure [X] may be further contained. Specifically, for example, in the aspect of <1>, an onium salt having the specific cation structure [X] may be further contained as the acid diffusion controller (C). In addition, in the aspect of <2>, an onium salt having the specific cation structure [X] may be further contained as the acid generator (B). Furthermore, in the aspects of <1> to <3>, another component that does not have the specific cation structure [X] may be further contained. For example, in the aspects of <1> to <3>, an onium salt having a cation which does not have the specific cation structure [X] (hereinafter also referred to as “other cation”) and an organic anion may be contained as the acid diffusion controller (C).

In the aspects <1> to <3>, the acid generator (B) and the acid diffusion controller (C) each may be a low-molecular-weight compound or each may be a polymer. When the acid generator (B) and the acid diffusion controller (C) are polymers, the polymers typically have the structural unit (IV). The polymer having the structural unit (I) together with the structural unit (IV) is classified as the polymer (A) in the present specification. On the other hand, the polymer that has the structural unit (IV) and does not have the structural unit (I) is classified into the acid generator (B) or the acid diffusion controller (C) according to the relative strength of the acid.

In the following, firstly, details of the structural unit (I) and the specific cation structure [X] will be described.

<Structural Unit (I)>

The structural unit (I) is a structural unit having an acid-dissociable group having a dinorbornane structure. In the present specification, the “acid-dissociable group” refers to a group that substitute a hydrogen atom in an acid group such as a carboxy group or a hydroxy group, and that dissociates by the action of an acid. When the polymer having the acid-dissociable group is contained in the composition, the acid-dissociable group is dissociated by an acid that has been generated from the compound having the radiation-sensitive onium cation through exposure, forms a carboxyl group, a hydroxy group or the like, and can change the solubility of the polymer component in a developer. Consequently, satisfactory lithographic properties can be imparted to the present composition, and a satisfactory resist pattern can be formed.

In particular, the composition contains a polymer having a bulky structure (dinorbornane structure) as the acid-dissociable group, and also the radiation-sensitive onium cation that has two or more of the substituents β, and thereby can achieve an improvement effect of enhancing the sensitivity and decreasing the development residue.

Examples of the monovalent hydrocarbon group having 1 to 20 carbon atoms represented by R² and R³ in the formula (i) include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms. R³ is a group bonded to one or more carbon atoms constituting the aliphatic hydrocarbon ring (specifically, dinorbornane skeleton) in the formula (i).

Examples of the monovalent chain hydrocarbon group having 1 to 20 carbon atoms include: alkyl groups such as a methyl group, an ethyl group, an n-propyl group, an i-propyl group; alkenyl groups such as an ethenyl group, a propenyl group and a butenyl group; and alkynyl groups such as an ethynyl group, a propynyl group and a butynyl group. Of these groups, the monovalent chain hydrocarbon groups having 1 to 20 carbon atoms represented by R² and R³ are each preferably an alkyl group, more preferably an alkyl group having 1 to 4 carbon atoms, and still more preferably a methyl group, an ethyl group and an i-propyl group.

Examples of the monovalent alicyclic hydrocarbon group having 3 to 20 carbon atoms include: monovalent monocyclic alicyclic saturated hydrocarbon groups such as a cyclopentyl group and a cyclohexyl group; monovalent monocyclic alicyclic unsaturated hydrocarbon groups such as a cyclopentenyl group and a cyclohexenyl group; monovalent polycyclic alicyclic saturated hydrocarbon groups such as a norbornyl group, an adamantyl group and a tricyclodecyl group; and monovalent polycyclic alicyclic unsaturated hydrocarbon groups such as a norbornenyl group and a tricyclodecenyl group. Of these groups, the monovalent monocyclic alicyclic saturated hydrocarbon group and the monovalent polycyclic alicyclic saturated hydrocarbon group are preferable, and the cyclopentyl group, the cyclohexyl group, the norbornyl group and the adamantyl group are more preferable.

Examples of the monovalent aromatic hydrocarbon group having 6 to 20 carbon atoms include: aryl groups such as a phenyl group, a tolyl group, a xylyl group, a mesityl group, a naphthyl group, a methylnaphthyl group, an anthryl group and a methylanthryl group; and aralkyl groups such as a benzyl group, a phenetyl group, a naphthylmethyl group and an anthrylmethyl group.

Examples of the alicyclic structure having 3 to 20 ring members formed by a plurality of R³ taken together include alicyclic saturated hydrocarbon structures such as a cyclopentane structure and a cyclohexane structure.

Of the above examples, R² preferably has 2 to 10 carbon atoms in such a point that a dissolution contrast can be enhanced, and more preferably has 2 to 5 carbon atoms in such a point that the dissociation occurs further easily. R³ is preferably a monovalent hydrocarbon group having 1 to 10 carbon atoms, more preferably a monovalent hydrocarbon group having 1 to 6 carbon atoms, in such a point that it is easy to control a polarity of the polymer having the structural unit (I). n is preferably 0 to 6, more preferably 0 to 3, and still more preferably 0 or 1.

In the formula (i), the arrangement of the polymer main chain to a bicyclo [2.2.1] heptane ring constituting the aliphatic hydrocarbon ring in the formula is not particularly limited, and may be any of an exo addition or an end addition to the bicyclo [2.2.1] heptane ring. Of these arrangements, the arrangement of the polymer main chain in the formula (i) is preferably the end addition to the bicyclo [2.2.1] heptane ring, and specifically is preferably a structural unit represented by each of formula (i-a) and formula (i-b), in a point of being capable of enhancing an LWR (line width roughness) performance, the CDU performance and a development residue suppressing property of the composition.

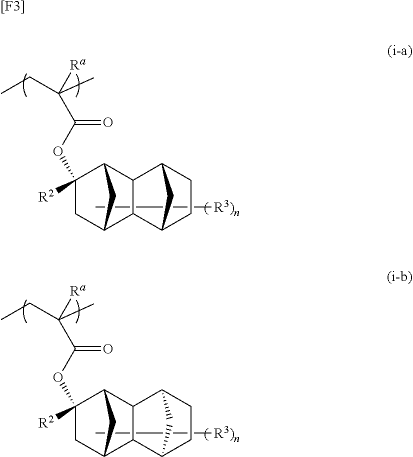

(In formula (i-a) and formula (i-b), R^{a}, R², R³ and n have the same meanings as those in the formula (i).)

Specific examples of the structural unit (I) include structural units represented by each of formula (i-1) to formula (i-7).

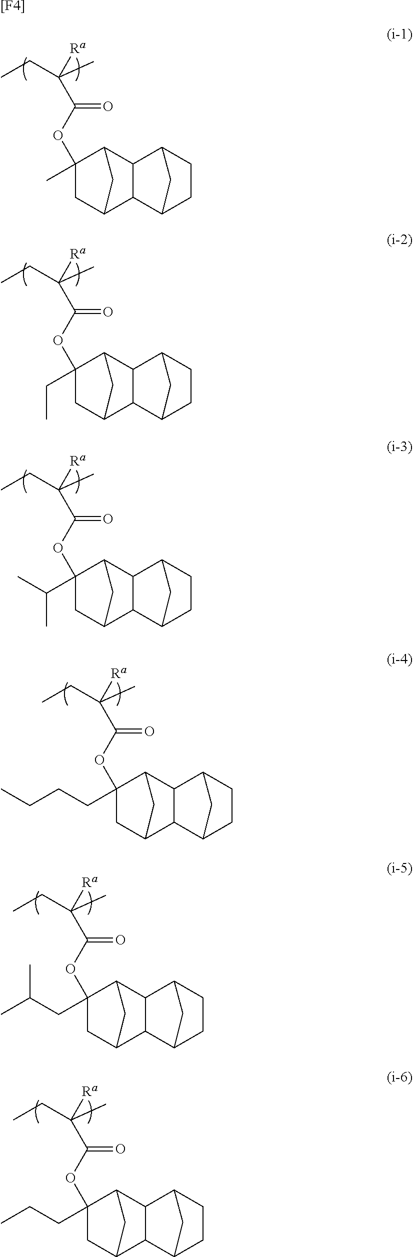

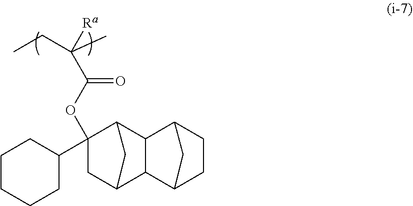

(In formula (i-1) to formula (i-7), R^{a} has the same meaning as that in the formula (i).)

In the polymer component contained in the composition, a content ratio of the structural unit (I) is preferably 3 mol % or more, more preferably 5 mol % or more, and still more preferably 10 mol % or more, with respect to all the structural units in the polymer (A). The content ratio of the structural unit (I) is preferably 80 mol % or less, more preferably 70 mol % or less, and still more preferably 65 mol % or less, with respect to all the structural units in the polymer (A). It is preferable to set the content ratio of the structural unit (I) in the range described above to appropriately adjust the solubility of the polymer (A) and reduction of the development residue.

<Specific Cation Structure [X]>

The specific cation structure [X] is not particularly limited as long as the specific cation structure [X] has a radiation-sensitive onium cation structure having two or more substituents β. It is preferable that the specific cation structure [X] has a sulfonium cation structure or an iodonium cation structure. To increase the sensitivity while the CDU performance and the solubility contrast in a developer of the composition are maintained high, the number of the substituents β in the specific cation structure [X] is preferably three or more, more preferably four or more. To achieve balance between the effect of sensitivity enhancement and the ease of synthesis, the number of the substituents β in the specific cation structure [X] is preferably 10 or less, more preferably 8 or less, still more preferably 7 or less, and further preferably 6 or less. The substituent β is preferably at least one group selected from the group consisting of a fluoro group and a fluoroalkyl group bonded to an aromatic ring, and more preferably the fluoro group bonded to an aromatic ring, from the viewpoint of the sensitivity.

When the specific cation structure [X] has a fluoroalkyl group as the substituent β, the number of fluoroalkyl groups in the specific cation structure [X] is equal to the number of the substituents β in the specific cation structure [X]. For example, when the specific cation structure [X] has two trifluoromethyl groups (—CF₃), the number of the substituents β in the specific cation structure [X] is two. When the specific cation structure [X] has one fluoro group (—F) and two trifluoromethyl groups (—CF₃) bonded to the aromatic ring, the number of the substituents β in the specific cation structure [X] results in being 3.

A bonding site of each substituent S in the specific cation structure [X] is not particularly limited. To achieve greater effect of sensitivity enhancement of the composition, it is preferable that at least one of the substituents β in the specific cation structure [X] is directly bonded to an aromatic ring in the specific cation structure [X], more preferably, two or more substituents β are directly bonded to the aromatic ring. In particular, it is preferable that: the specific cation structure [X] has one or two or more aromatic rings bonded to a sulfonium cation or an iodonium cation (hereinafter also referred to as “aromatic ring Z”); and two or more substituents β are bonded to the same or different aromatic rings Z. In other words, it is preferable that the specific cation structure [X] has one or more aromatic rings Z; and two or more substituents β are bonded to the same aromatic ring among one or more of the aromatic rings Z. Alternatively, it is preferable that: the specific cation structure [X] has two or more aromatic rings Z; and one or more substituents β are bonded to each of different aromatic rings of the two or more aromatic rings Z.

Examples of the aromatic ring Z include a benzene ring, a naphthalene ring and an anthracene ring. Among these, the benzene ring or the naphthalene ring is preferable for the aromatic ring Z, and the benzene ring is more preferable. The number of aromatic rings Z in the specific cation structure [X] is not particularly limited. The number of aromatic rings Z in the specific cation [X] is preferably one or more, more preferably two or more. With respect to the total number of the substituents β bonded to the aromatic ring Z in the specific cation structure [X], the description of the number of the substituents β in the specific cation structure [X] may be referred. That is, the total number of substituents β bonded to the aromatic ring Z is preferably three or more, more preferably four or more. To achieve the balance between the effect of sensitivity enhancement and the ease of synthesis, the total number of substituents β bonded to the aromatic ring Z is preferably 10 or less, more preferably 8 or less, still more preferably 7 or less, and further preferably 6 or less.

It is especially preferable that the specific cation structure [X] has a triarylsulfonium cation structure or a diaryliodonium cation structure. Specifically, it is preferable that the specific cation structure [X] is a partial structure represented by formula (1) or a structure represented by formula (2).

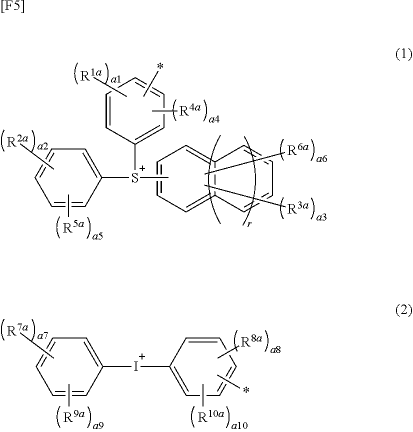

(In formula (1), Ria, R^{2a} and R^{3a} each independently represent a fluoro group or a fluoroalkyl group; R^{4a} and R^{5a} each independently represent a monovalent substituent, or R^{4a} and R^{5a} taken together represent a single bond or a divalent group connecting rings to which the R^{4a} and R^{5a} bond respectively; R^{6a} represents a monovalent substituent; a1 represents an integer of 0 to 4, a2 and a3 each independently represent an integer of 0 to 5, provided that a1+a2+a3≥2; a4, a5 and a6 each independently represent an integer of 0 to 3, r represents 0 or 1, provided that a1+a4≤4, a2+a5≤5, and a3+a6≤2×r+5; and “*” represents a bonding hand.

In formula (2), R^{7a} and R^{8a} each independently represents a fluoro group or a fluoroalkyl group; R^{9a} and R^{10a} each independently represent a monovalent substituent; a7 represents an integer of 0 to 5, a8 represents an integer of 0 to 4, provided that a7+a8≥2; a9 and a10 each independently represent an integer of 0 to 3, provided that a7+a9<5 and a8+a10<4; and “*” represents a bonding hand.)

In the formula (1) and formula (2), the fluoroalkyl groups of Ria, R^{2a}, R^{3a}, R^{7a} and R^{8a} may be linear or branched. The fluoroalkyl group preferably has 1 to 10 carbon atoms. Examples of the fluoroalkyl group include a trifluoromethyl group, a 2,2,2-trifluoroethyl group, a perfluoroethyl group, a 2,2,3,3,3-pentafluoropropyl group, a 1,1,1,3,3,3-hexafluoropropyl group, a perfluoro n-propyl group, a perfluoroisopropyl group, a perfluoro n-butyl group, a perfluoroisobutyl group, a perfluoro t-butyl group, a 2,2,3,3,4,4,5,5-octafluoropentyl group, and a perfluorohexyl group. Of the groups, the fluoroalkyl groups of Ria, R^{2a}, R^{3a}, R^{7a} and R^{8a} are each preferably a group having 1 to 5 carbon atoms, more preferably the trifluoromethyl group, the 2,2,2-trifluoroethyl group or the perfluoroethyl group.

Of these examples, R^{1a}, R^{2a}, R^{3a}, R^{7a} and R^{8a} are each preferably the fluoro group, the trifluoromethyl group, the 2,2,2-trifluoroethyl group or the perfluoroethyl group, more preferably the fluoro group or the trifluoromethyl group, and particularly preferably the fluoro group. When an onium salt having a structure in which the fluoro group is directly bonded to an aromatic ring in a triarylsulfonium cation structure or a diaryliodonium cation structure is used, the sensitivity of the composition can be further enhanced, and the composition can be obtained that is excellent in the CDU performance and a development residue suppressing property.

In formula (1) and formula (2), monovalent substituents represented by R^{4a}, R^{5a}, R^{6a}, R^{9a} and R^{10a} are each a group different from the substituent β. Specific examples of the monovalent substituent represented by R^{4a}, R^{5a}, R^{6a}, R^{9a} and R^{10a} include a chloro group, a bromo group, an iodo group, a substituted or unsubstituted alkyl group (provided that fluoroalkyl groups are excluded), a substituted or unsubstituted alkoxy group, a substituted or unsubstituted cycloalkyl group, a substituted or unsubstituted cycloalkyloxy group, an ester group, an alkylsulfonyl group, a cycloalkylsulfonyl group, a hydroxy group, a carboxy group, a cyano group and a nitro group.

Alkyl groups represented by R^{4a}, R^{5a}, R^{6a}, R^{9a} and R^{10a} may be linear or branched. The alkyl group preferably has 1 to 10 carbon atoms. Examples of such an alkyl group include a methyl group, an ethyl group, an n-propyl group, an i-propyl group, a n-butyl group, an i-butyl group, a sec-butyl group, a t-butyl group, an n-pentyl group and a neopentyl group. Of these groups, the alkyl groups of R^{4a}, R^{5a}, R^{6a}, R^{9a} and Rica each preferably have 1 to 5 carbon atoms, and are more preferably each a methyl group, an ethyl group, an n-butyl group or a t-butyl group. When the alkyl groups of R^{4a}, R^{5a}, R^{6a}, R^{9a} and Rica each have a substituent, examples of the substituent include a chloro group, a bromo group, an iodo group, a hydroxy group, a carboxy group, a cyano group, a nitro group, and an alkoxy group having 1 to 5 carbon atoms.

Specific examples of the substituted or unsubstituted alkoxy groups represented by R^{4a}, R^{5a}, R^{6a}, R^{9a} and R^{10a} include groups that have the substituted or unsubstituted alkyl group in the previous examples at an alkyl group moiety constituting the alkoxy group. It is particularly preferable for the alkoxy group to be a methoxy group, an ethoxy group, an n-propoxy group or an n-butoxy group.

The cycloalkyl groups represented by R^{4a}, R^{5a}, R^{6a}, R^{9a} and Rica may be each either monocyclic or polycyclic. Of these cycloalkyl groups, examples of monocyclic cycloalkyl groups include a cyclopropyl group, a cyclobutyl group, a cyclopentyl group, a cyclohexyl group and a cyclooctyl group. Examples of the polycyclic cycloalkyl groups include a norbornyl group, an adamantyl group, a tricyclodecyl group and a tetracyclododecyl group. When the cycloalkyl groups of R^{4a}, R^{5a}, R^{6a}, R^{9a} and Rica each have a substituent, examples of the substituent include a chloro group, a bromo group, an iodo group, a hydroxy group, a carboxy group, a cyano group, a nitro group, and an alkoxy group having 1 to 5 carbon atoms.

Specific examples of the substituted or unsubstituted cycloalkyloxy group represented by R^{4a}, R^{5a}, R^{6a}, R^{9a} and Rica include groups that have the substituted or unsubstituted cycloalkyl groups in the previous example at cycloalkyl group moiety constituting the cycloalkyloxy group. It is particularly preferable for the alkoxy group to be a cyclopentyloxy group or a cyclohexyloxy group.

When R^{4a}, R^{5a}, R^{6a}, R^{9a} and R^{10a} each represent an ester group (—COOR), examples of a hydrocarbon moiety (R) of the ester group include the substituted or unsubstituted alkyl groups or the substituted or unsubstituted cycloalkyl groups in the previous examples. Of these groups, when R^{4a}, R^{5a}, R^{6a}, R^{9a} and R^{10a} are each an ester group, the group is preferably a methoxycarbonyl group, an ethoxycarbonyl group or an n-butoxycarbonyl group.

When R^{4a}, R^{5a}, R^{6a}, R^{9a} and R^{10a} are each an alkylsulfonyl group, examples of an alkyl group moiety constituting the alkylsulfonium group include the substituted or unsubstituted alkyl groups in the previous examples. When R^{4a}, R^{5a}, R^{6a}, R^{9a} and R^{10a} are each a cycloalkylsulfonyl group, examples of an alkyl group moiety constituting the cycloalkylsulfonium group include the substituted or unsubstituted cycloalkyl groups in the previous examples.

When R^{4a} and R^{5a} taken together represent a divalent group connecting the rings to which the R^{4a} and R^{5a} bond respectively, examples of the divalent groups include: —COO—, —OCO—, —CO—, —O—, —SO—, —SO₂— and —S—; an alkanediyl group having 1 to 3 carbon atoms; an alkenediyl group having 2 or 3 carbon atoms; and a group having —O—, —S—, —COO—, —OCO—, —CO—, —SO— or —SO₂-in between carbon and carbon of a bond of an ethylene group. Of these examples, when R^{4a} and R^{5a} taken together represent a single bond or a divalent group connecting the rings to which the R⁴ and R^{5a} bond respectively, R⁴ and R^{5a} each preferably form a single bond, —O— or —S—.

The total number of a1, a2 and a3 is 2 or more, more preferably 3 or more, still more preferably 3 to 6, and further preferably 4 to 6.

The total number of a7 and a8 is 2 or more, more preferably 2 to 6.

The bonding hand (*) in the formula (1) and formula (2) may be bonded to a hydrogen atom, or may be bonded to a monovalent group (a fluoro group, a hydroxy group, an alkyl group, or the like). Alternatively, the bonding hand may be bonded to an atom constituting the main chain or the side chain of the polymer.

Examples of the specific cation structure [X] include structures represented by the following formulae and such structures that one arbitrary hydrogen atom is removed from a benzene ring in each of the organic cations represented by the following formulae. The structures included in the specific cation [X] are not limited to the following structures.

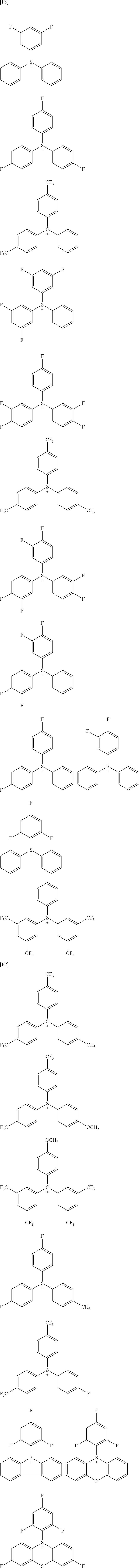

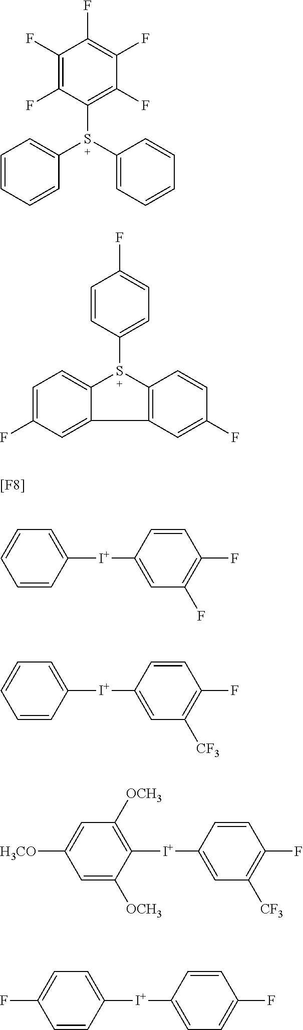

The organic anion that serves as a counter ion of the specific cation structure [X] is not particularly limited as long as the organic anion has a structure capable of generating an acid through irradiation with radioactive rays. Examples of the structure in the organic anion include a sulfonate anion structure, an imide anion structure, a methyl anion structure and a carboxylate anion structure. Of these structures, the organic anion preferably has the sulfonate anion structure or the carboxylate anion structure.

<Specific Aspects of the Composition>

One preferable aspect of the present composition is a polymer composition that includes the polymer (A) and the acid generator (B), and may further include one or more of the acid diffusion controller (C), a solvent (D) and a high fluorine-containing polymer (E), as suitable components. Each component will be described in detail below.

<Polymer (A)>

The polymer (A) is a polymer including the structural unit (I) described above. The polymer (A) preferably constitutes a base resin of the composition. The “base resin” in the present specification means a component that occupies 50 mass or more with respect to the total amount of solid contents included in the composition. The composition may include only one type of polymer (A), or may include two or more types. In the present specification, the “total amount of solid contents” is the sum total of components other than the solvent (D).

A content ratio of the structural unit (I) in the polymer (A) is preferably 3 mol % or more, more preferably 5 mol % or more, and still more preferably 10 mol % or more, with respect to all the structural units constituting the polymer (A). The content ratio of the structural unit (I) is preferably 80 mol % or less, more preferably 70 mol % or less, and still more preferably 65 mol % or less, with respect to all the structural units constituting the polymer (A). It is preferable to set the content ratio of the structural unit (I) in the range described above to improve the sensitivity of the composition.

[Other Structural Units]

The polymer (A) may further include structural units different from the structural unit (I) (hereinafter also referred to as “other structural units”). Examples of the other structural units include structural units (II) to (VI) listed below.

Structural unit (II): a structural unit having a hydroxyl group bonded to an aromatic ring.

Structural unit (III): a structural unit having an acid-dissociable group that does not have a dinorbornane structure.

Structural unit (IV): a structural unit having a radiation-sensitive onium cation and an organic anion.

Structural unit (V): having a lactone structure, a cyclic carbonate structure, a sultone structure, or a ring structure in which two or more of these structures are combined with each other.

Structural unit (VI): a structural unit having an alcoholic hydroxyl group.

[Structural Unit (II)]

The polymer (A) preferably further includes a structural unit (II) having a hydroxyl group bonded to an aromatic ring. When the structural unit (II) is introduced into the polymer (A), the lithographic properties (LWR performance, CDU performance and the like) of the composition can be sufficiently enhanced, which is preferable.

Examples of the aromatic ring included in the structural unit (II) include a benzene ring, a naphthalene ring and an anthracene ring. Of these aromatic rings, the benzene ring or the naphthalene ring is preferable, and the benzene ring is more preferable. The number of hydroxyl groups bonded to the aromatic ring in the structural unit (II) is not particularly limited. The number of hydroxyl groups bonded to the aromatic ring in the structural unit (II) is preferably 1 to 3, more preferably 1 or 2. Examples of the structural unit (II) include a structural unit represented by formula (ii).

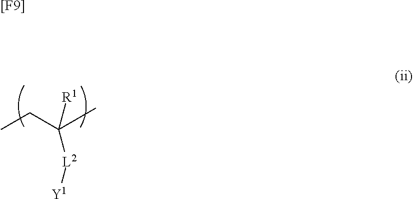

(In formula (ii), R¹ is a hydrogen atom, a fluoro group, a methyl group or a trifluoromethyl group; L² is a single bond, —O—, —CO—, —COO— or —CONH—; and Y¹ is a monovalent group having a hydroxyl group bonded to an aromatic ring.)

In the formula (ii), R¹ is preferably the hydrogen atom or the methyl group, from the viewpoint of copolymerizability of a monomer that gives the structural unit (II). L² is preferably the single bond or —COO—.

Specific examples of the structural unit (II) include structural units that are represented by formula (1-1) to formula (1-12), respectively.

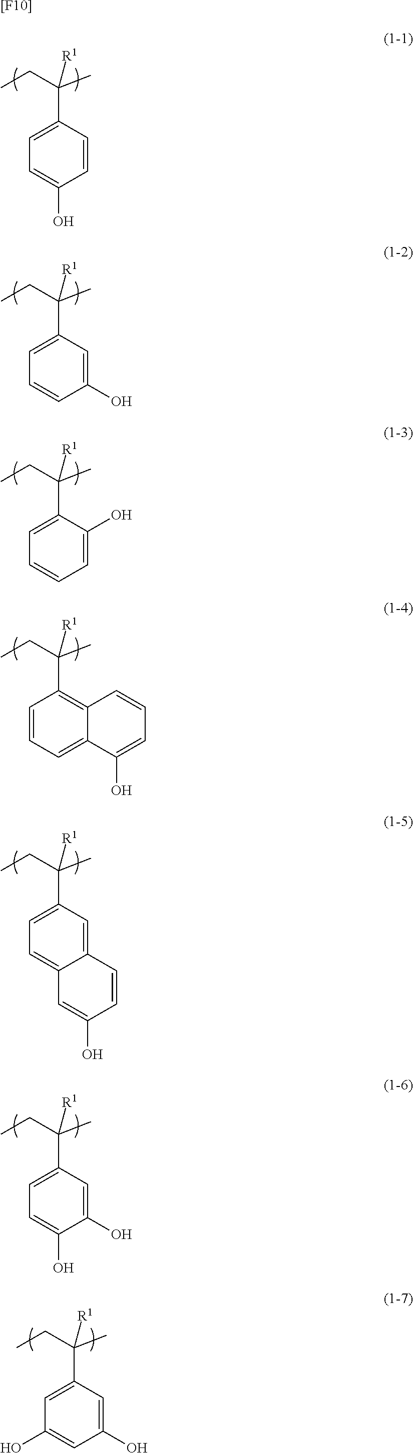

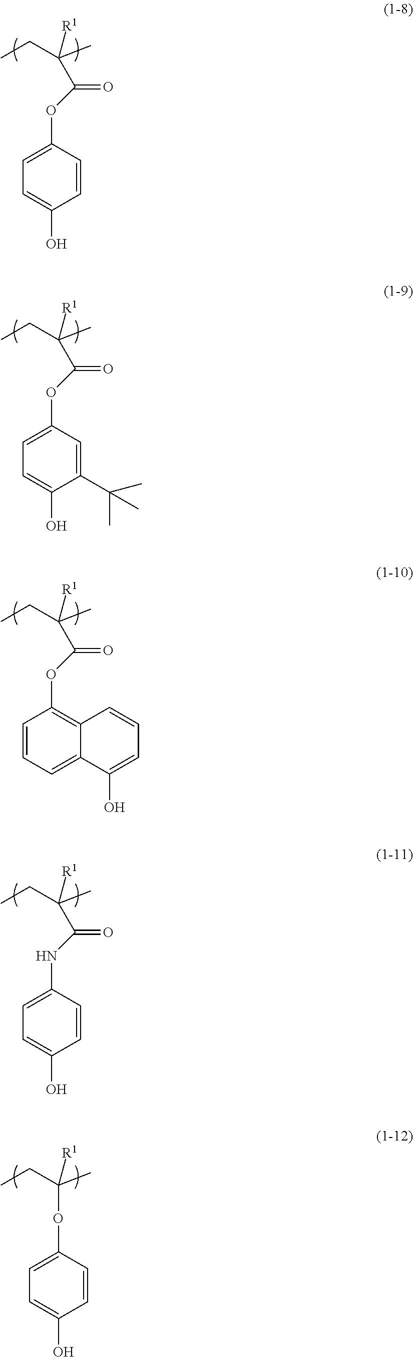

(In formula (1-1) to formula (1-12), R¹ is a hydrogen atom, a fluoro group, a methyl group or a trifluoromethyl group.)

The proportion of the structural unit (II) in the polymer (A) is preferably 5 mol % or more, more preferably 10 mol % or more, and still more preferably 20 mol % or more with respect to all the structural units constituting the polymer (A). The proportion of the structural unit (II) is preferably 80 mol % or less, more preferably 70 mol % or less, and still more preferably 60 mol % or less, with respect to all the monomers constituting the polymer (A). It is preferable to set the proportion of the structural unit (II) in the range described above to sufficiently enhance lithographic properties (LWR performance, CDU performance, and the like) of the composition.

To sufficiently enhance the LWR performance, the CDU performance and the like of the composition, the composition preferably includes a polymer having a structural unit (II), and the aspect is not particularly limited. Accordingly, the composition may contain a polymer having the structural unit (II) separately from a polymer having a structural unit (I) (that is, the polymer (A)). Examples of the specific aspects of the composition in this case include: an aspect that includes a polymer that has the structural unit (I) and does not have the structural unit (II), and a polymer that has the structural unit (II) and does not have the structural unit (I); and an aspect that includes a polymer that has the structural unit (I) and the structural unit (II), and a polymer that has the structural unit (II) and does not have the structural unit (I). To obtain a composition having excellent lithographic properties including a defect-suppressing property, a LWR performance and the CDU performance, the composition preferably includes at least the polymer having the structural unit (I) and the structural unit (II) as the polymer (A).

[Structural Unit (III)]

The structural unit (III) is a structural unit having an acid-dissociable group. The structural unit (III) is different from the structural unit (I) in such a point as not to have the dinorbornane structure. The structural unit (III) is not particularly limited as long as the structural unit (III) has a group (an acid-dissociable group) that substitutes a hydrogen atom contained in an acid group such as a carboxy group or a hydroxy group and is dissociated by the action of an acid. Specific examples of the structural unit (III) include a structural unit that is represented by formula (iii-1) (hereinafter also referred to as “structural unit (III-1)”) and a structural unit that is represented by formula (iii-2) (hereinafter also referred to as “structural unit (III-2)”).

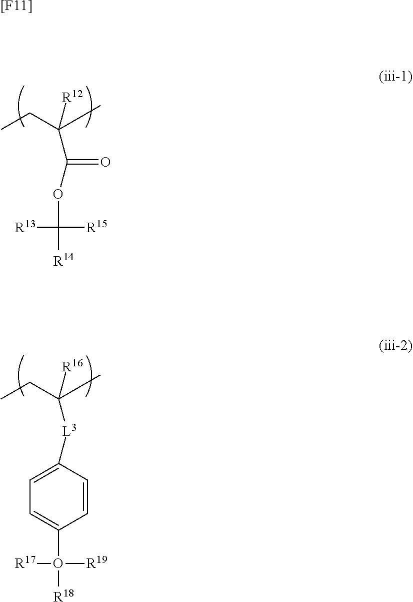

(In formula (iii-1), R¹² is a hydrogen atom, a fluoro group, a methyl group or a trifluoromethyl group; R¹³ is a monovalent hydrocarbon group having 1 to 20 carbon atoms; and R¹⁴ and R¹⁵ each independently represent a monovalent hydrocarbon group having 1 to 20 carbon atoms, or R¹⁴ and R¹⁵ taken together represent an alicyclic structure having 3 to 20 carbon atoms together with a carbon atom to which R¹⁴ and R¹⁵ bond.

In formula (iii-2), R¹⁶ is a hydrogen atom or a methyl group; L³ is a single bond, —COO— or —CONH—; and R¹⁷, R¹⁸ and R¹⁹ are each independently a hydrogen atom, a monovalent hydrocarbon group having 1 to 20 carbon atoms, or a monovalent oxyhydrocarbon group having 1 to 20 carbon atoms.)

In the formula (iii-1) and formula (iii-2), R¹² is preferably a hydrogen atom or a methyl group, more preferably the methyl group, from the viewpoint of copolymerizability of a monomer giving the structural unit (III-1). R¹⁶ is preferably a hydrogen atom, from the viewpoint of the copolymerizability of a monomer that gives the structural unit (III-2).

Examples of the monovalent hydrocarbon group having 1 to 20 carbon atoms represented by R¹³ to R¹⁵ and R¹⁷ to R¹⁹ include: a monovalent chain hydrocarbon group having 1 to 20 carbon atoms; a monovalent alicyclic hydrocarbon group having 3 to 20 carbon atoms; and a monovalent aromatic hydrocarbon group having 6 to 20 carbon atoms. Specific examples of the monovalent chain hydrocarbon group having 1 to 20 carbon atoms include: alkyl groups such as a methyl group, an ethyl group, an n-propyl group, an i-propyl group, an n-butyl group, an i-butyl group, a sec-butyl group, a t-butyl group and a pentyl group; alkenyl groups such as an ethenyl group, a propenyl group, a butenyl group and a pentenyl group; and alkynyl groups such as an ethynyl group, a propynyl group, a butynyl group and a pentinyl group.

Examples of the monovalent alicyclic hydrocarbon group having 3 to 20 carbon atoms include: monocyclic alicyclic saturated hydrocarbon groups such as a cyclopropyl group, a cyclobutyl group, a cyclopentyl group, and a cyclohexyl group; polycyclic alicyclic saturated hydrocarbon groups such as a norbornyl group, an adamantyl group, a tricyclodecyl group, and a tetra-cyclododecyl group; monocyclic alicyclic unsaturated hydrocarbon groups such as a cyclopropenyl group, a cyclobutenyl group, a cyclopentenyl group, and a cyclohexenyl group; and polycyclic alicyclic saturated hydrocarbon groups such as a norbornenyl group and a tricyclodecenyl group.

Examples of the monovalent aromatic hydrocarbon group having 6 to 20 carbon atoms include: aryl groups such as a phenyl group, a tolyl group, a xylyl group, a naphthyl group and an anthryl group; and aralkyl groups such as a benzyl group, a phenetyl group, a naphthylmethyl group and an anthrylmethyl group.

Examples of the alicyclic structure having 3 to 20 carbon atoms formed by R¹⁴ and R¹⁵ taken together with a carbon atom to which R¹⁴ and R¹⁵ bond include: monocyclic alicyclic structures such as a cyclopropane structure, a cyclobutane structure, a cyclopentane structure, a cyclohexane structure, a cycloheptane structure and a cyclooctane structure; and polycyclic alicyclic structures such as a norbornane structure, an adamantane structure, a tricyclodecane structure and a tetracyclododecane structure.

Examples of the monovalent oxyhydrocarbon group having 1 to 20 carbon atoms represented by R¹⁷, R¹⁸ and R¹⁹ include the examples of the monovalent hydrocarbon groups having 1 to 20 carbon atoms of R¹³ to R¹⁵ and R¹⁷ to R¹⁹ each have an oxygen atom at the terminal of the bonding hand side described above.

Of these groups, R¹⁷, R¹⁸ and R¹⁹ are preferably a chain hydrocarbon group or a cycloalkyloxy group.

Specific examples of the structural unit (III-1) include structural units represented by the following formulae.

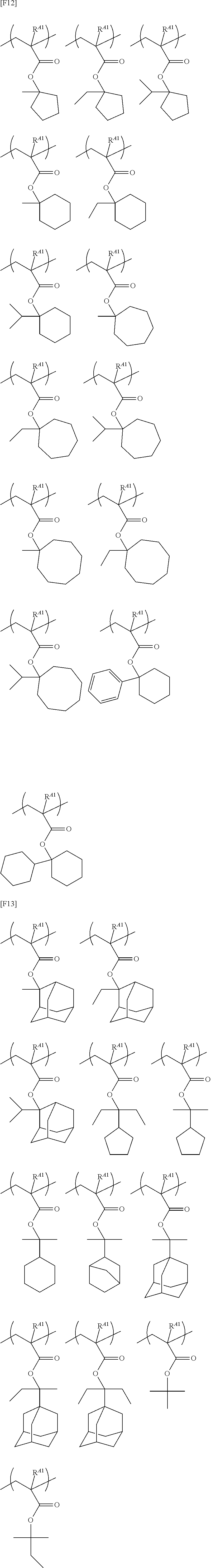

(In the formulae, R^{A1} represents a hydrogen atom, a fluoro group, a methyl group or a trifluoromethyl group.)

Specific examples of the structural unit (III-2) include structural units represented by the following formulae.

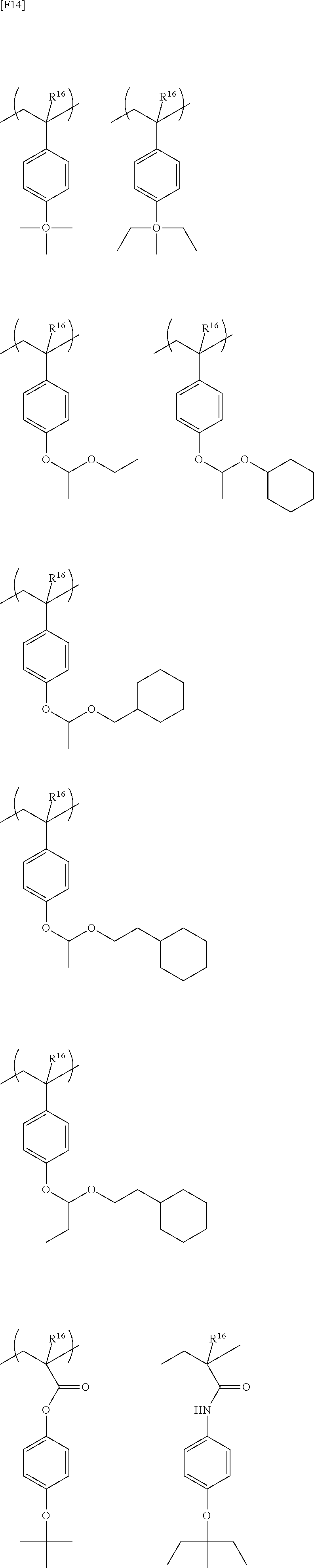

(In the formulae, R¹⁶ represents a hydrogen atom or a methyl group.)

In the polymer (A), a content ratio of the total of the structural unit (I) and the structural unit (III) is preferably 20 mol % or more, more preferably 25 mol % or more, and still more preferably 30 mol % or more, with respect to all the structural units constituting the polymer (A). A content ratio of the total of the structural unit (I) and the structural unit (III) is preferably 80 mol % or less, more preferably 70 mol % or less, and still more preferably 65 mol % or less, with respect to all the structural units constituting the polymer (A). It is preferable to set the content ratio of the structural unit (III) in the range described above to sufficiently increase a difference in a dissolution rate between the exposed portion and the unexposed portion in the developer and to improve a pattern shape of the resist film.

[Structural Unit (IV)]

The structural unit (IV) is typically a structural unit that is derived from an onium salt having a group that is involved in polymerization (preferably a group that contains a polymerizable carbon-carbon unsaturated bond). It is preferable that the polymer (A) includes the structural unit (IV) for further enhancement of the development residue-reducing effect. The structural unit (IV) can be specifically represented as a structural unit that is derived from each of monomers represented by formula (4A) or formula (4B).

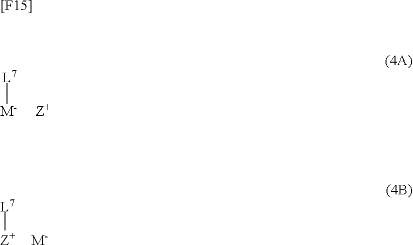

(In formula (4A), L⁷ represents a group involved in polymerization; “L⁷-Z⁺” represents a radiation-sensitive onium cation; and “M-” represents an organic anion. In formula (4B), L⁷ represents a group involved in polymerization; “Z⁺” represents a radiation-sensitive onium cation; and “L⁷-M-” represents an organic anion.)

In the formula (4A) and formula (4B), a group represented by L⁷ is preferably a group that has a polymerizable carbon-carbon unsaturated bond. Specific examples of the group include a vinyl group, a vinyl ether group, a vinyl phenyl group, a (meth)acryloyl group and a maleimide group.

For the ease of synthesis of the polymer, the structural unit (IV) is preferably a structural unit that is derived from a monomer represented by formula (4B) between the formulae.

A radiation-sensitive onium cation contained in a monomer constituting the structural unit (IV) may be a radiation-sensitive onium cation having two or more substituents β, or may be a radiation-sensitive onium cation that has only one substituent β or does not have the substituent β (hereinafter also referred to as “other organic cation”). Examples of the monomer constituting the structural unit (IV) include the monomers [A1] and [A2] listed below.

[A1] A monomer that includes a radiation-sensitive onium cation having two or more substituents β and an organic anion, and in which any of the radiation-sensitive onium cation having two or more of the substituents β and the organic anion has a group involved in the polymerization.

[A2] A monomer that is composed of the other organic cation and an organic anion, and in which any one of the other organic cation and the organic anion has a group involved in the polymerization.

Preferable examples of the structural unit (IV) include a structural unit represented by formula (iv-1), a structural unit represented by formula (iv-2), and a structural unit represented by formula (iv-3).

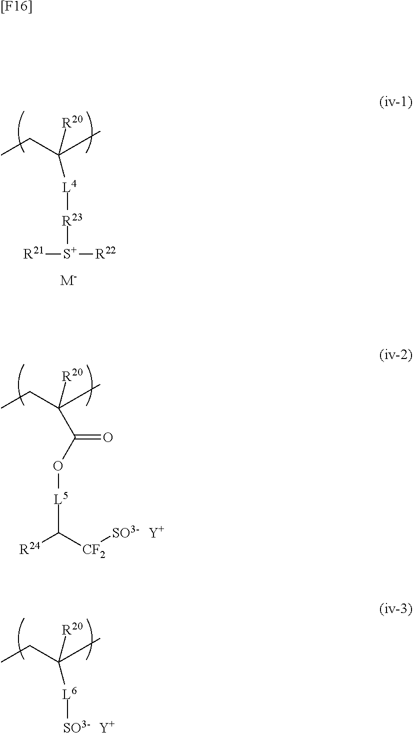

(In formula (iv-1), R²⁰ represents a hydrogen atom or a methyl group; L⁴ represents a single bond, —O— or —COO—; R²³ represents a substituted or unsubstituted alkanediyl group having 1 to 6 carbon atoms, a substituted or unsubstituted alkenediyl group having 2 to 6 carbon atoms, or a substituted or unsubstituted arylene group having 6 to 12 carbon atoms; R²¹ and R²² each independently represent a substituted or unsubstituted alkyl group having 1 to 12 carbon atoms, a substituted or unsubstituted alkenyl group having 2 to 12 carbon atoms, or a substituted or unsubstituted aryl group having 6 to 20 carbon atoms; and M⁻ represents an organic anion.

In formula (iv-2), R²⁰ represents a hydrogen atom or a methyl group; L⁵ represents a single bond, —R^{30a}—CO—O—, —R^{30a}—O—, or —R^{30a}—O—CO—; R^{30a} represents a divalent group such as an alkanediyl group having 1 to 12 carbon atoms, or a divalent group that includes —O—, —CO— or —COO— in between carbon and carbon of a bond of an alkanediyl group having 2 to 12 carbon atoms; R²⁴ represents a hydrogen atom, an alkyl group having 1 to 10 carbon atoms, or a fluoroalkyl group having 1 to 10 carbon atoms; and Y⁺ represents a radiation-sensitive onium cation represented by formula (Y-1) or formula (Y-2).

In formula (iv-3), R²⁰ represents a hydrogen atom or a methyl group; L⁶ represents a single bond, a substituted or unsubstituted alkanediyl group having 1 to 6 carbon atoms, a substituted or unsubstituted alkenediyl group having 2 to 6 carbon atoms, a substituted or unsubstituted arylene group having 6 to 12 carbon atoms, —CO—O—R^{30b}— or —CO—NH—R^{30b}—; R^{30b} represents a substituted or unsubstituted alkanediyl group having 1 to 6 carbon atoms, or a divalent group including —O—, —CO— or —COO— in between carbon and carbon of a bond of an alkanediyl group having 2 to 6 carbon atoms; and Y⁺ represents a radiation-sensitive onium cation represented by formula (Y-1) or formula (Y-2).)

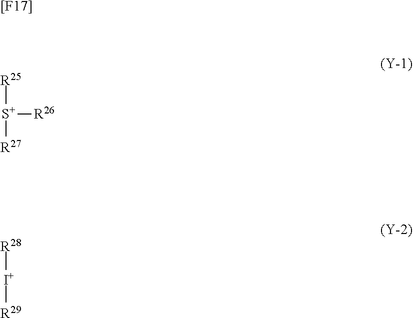

(In formula (Y-1) and formula (Y-2), R²⁵ to R²⁹ each independently represent a substituted or unsubstituted alkyl group having 1 to 12 carbon atoms, a substituted or unsubstituted alkenyl group having 2 to 12 carbon atoms, or a substituted or unsubstituted aryl group having 6 to 20 carbon atoms.)

When each group of R²¹ to R²³ and R²⁵ to R²⁹ is a substituted alkyl group, a substituted alkenyl group or a substituted aryl group in formula (iv-1) to formula (iv-3), and in formula (Y-1) and formula (Y-2), examples of the substituents include a fluoro group, a chloro group, a bromo group, an iodo group, an alkoxy group, a cycloalkyloxy group, an ester group, an alkylsulfonyl group, a cycloalkylsulfonyl group, a hydroxy group, a carboxy group, a cyano group, a nitro group, an acetyl group and a fluoroacetyl group.

An organic cation in the monomer constituting the structural unit represented by the formula (iv-1) and the organic cation represented by the formula (Y-1) preferably include a triarylsulfonium cation structure. Organic cations in the formula (iv-2) and formula (iv-3) preferably include a triarylsulfonium cation structure or a diaryliodonium cation structure. An organic cation represented by the formula (Y-2) preferably includes a diaryliodonium cation structure. In the examples in which the monomers constituting the structural unit represented by the formula (iv-1), the structural unit represented by the formula (iv-2) or the structural unit represented by the formula (iv-3) include the specific cation structure [X], specific examples of the specific cation structure [X] include the structures in the previous examples.

Specific examples of the structural unit (IV) include structural units represented by formula (iv-la) to formula (iv-7a) as structural units including partial structures represented by the formula (4B). Examples of structural units including partial structures represented by the formula (4A) include structural units represented by formula (iv-8a) and formula (iv-9a), respectively.

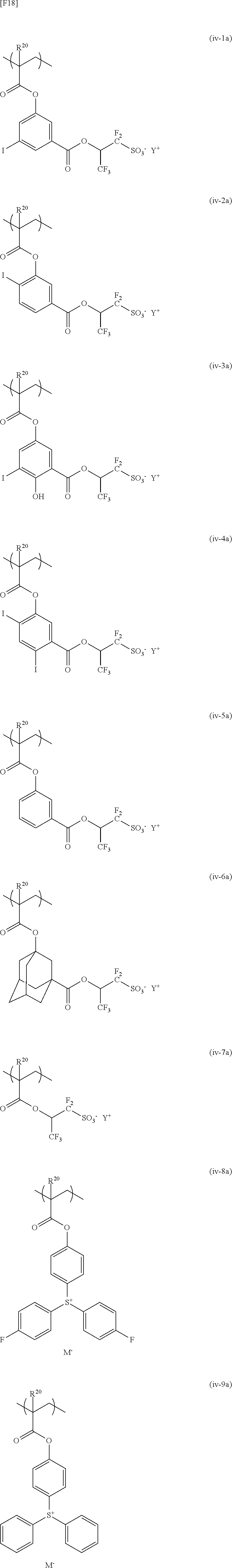

(In formula (iv-la) to formula (iv-9a), R²⁰ represents a hydrogen atom or a methyl group; Y⁺ represents a radiation-sensitive onium cation represented by formula (Y-1) or formula (Y-2); and M⁻ represents an organic anion.)

When the polymer (A) includes the structural unit (IV), a content ratio of the structural unit (IV) is preferably 3 mol % or more, more preferably 5 mol % or more, and still more preferably 10 mol % or more, with respect to all the structural units constituting the polymer (A). The content ratio of the structural unit (IV) is preferably 50 mol % or less, more preferably 35 mol % or less, and still more preferably 25 mol % or less, with respect to all the structural units constituting the polymer (A). It is preferable to set the content ratio of the structural unit (IV) in the range described above to suppress a decrease in resolution caused particularly by acid diffusion and thus lithographic properties of the composition can be further enhanced.

[Structural Unit (V)]

The structural unit (V) is a structural unit that includes a lactone structure, a cyclic carbonate structure, a sultone structure, or such a ring structure that two or more of these structures are combined (provided that those corresponding to the structural units (I) to (IV) are excluded). It is preferable that the polymer (A) further includes the structural unit (V) to adjust the solubility in a developer and thus lithographic properties of the composition can be further improved. The polymer (A) that further includes the structural unit (V) can improve adhesiveness between the resist film obtained with use of the composition and the substrate.

Examples of the structural unit (V) include structural units represented by the following formulae.

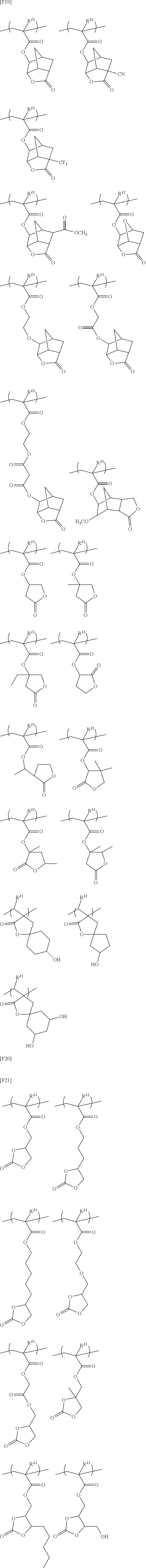

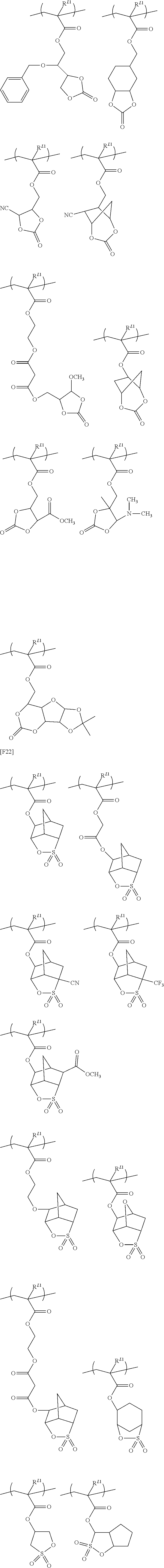

(In the formulae, R^{L1} represents a hydrogen atom, a fluoro group, a methyl group or a trifluoromethyl group.)

When the polymer (A) includes the structural unit (V), the content ratio of the structural unit (V) is preferably 5 mol % or more, more preferably 10 mol % or more, and still more preferably 15 mol % or more, with respect to all the structural units constituting the polymer (A). A content ratio of the structural unit (V) is preferably 50 mol % or less, more preferably 40 mol % or less, and still more preferably 30 mol % or less, with respect to all the structural units constituting the polymer (A). It is preferable to set the content ratio of the structural unit (V) in the range described above to enhance the lithographic properties of the composition and the adhesiveness of the resist film obtained with use of the composition to the substrate.

[Structural Unit (VI)]

The structural unit (VI) is a structural unit that includes an alcoholic hydroxyl group (provided that those corresponding to the structural units (I) to (V) are excluded). In the present disclosure, “alcoholic hydroxyl group” refers to a group including a structure in which a hydroxyl group is directly bonded to an aliphatic hydrocarbon group. The aliphatic hydrocarbon group may be a chain hydrocarbon group or may be an alicyclic hydrocarbon group. It is preferable that the polymer (A) further includes the structural unit (VI) to improve the solubility in a developer and thus lithographic properties of the composition can be further improved.

The structural unit (VI) is preferably a structural unit derived from an unsaturated monomer having an alcoholic hydroxyl group. Examples of the unsaturated monomer include, but not limited to, 3-hydroxyadamantane-1-yl (meth)acrylate, and 2-hydroxyethyl (meth)acrylate.

When the polymer (A) includes the structural unit (VI), a content ratio of the structural unit (VI) is preferably 1 mol % or more, and more preferably 3 mol % or more, with respect to all the structural units constituting the polymer (A). The content ratio of the structural unit (VI) is preferably 30 mol % or less, and more preferably 10 mol % or less, with respect to all the structural units constituting the polymer (A).

In addition to the above, examples of the other structural units include: a structural unit having a cyano group, a nitro group or a sulfonamide group (for example, structural units derived from 2-cyanomethyladamantane-2-yl (meth)acrylate and the like); structural units having a halogen atom (for example, a structural unit derived from 2,2,2-trifluoroethyl (meth)acrylate, a structural unit derived from 1,1,1,3,3,3-hexafluoropropan-2-yl (meth)acrylate, a structural unit derived from 4-iodostyrene and the like); and structural units having a non-acid-dissociable hydrocarbon group (for example, a structural unit derived from styrene, a structural unit derived from vinyl naphthalene, a structural unit derived from n-pentyl (meth)acrylate and the like). A content ratio of each of these structural units can be set, in accordance with each of the structural units, in an appropriate range such that the effect of the disclosure is not impaired.

A content ratio of the polymer (A) in the composition is preferably 50% by mass or more, more preferably 70% by mass or more, and still more preferably 80% by mass or more, with respect to the total amount of the solid contents contained in the composition. The content ratio of the polymer (A) is preferably 99% by mass or less, more preferably 98% by mass or less, and still more preferably 95% by mass or less, with respect to the total amount of the solid contents contained in the composition. It is preferable to set the ratio of the polymer (A) to the total amount of the solid contents contained in the composition in the range described above to achieve excellent sensitivity and CDU performance of the composition and sufficient effect of enhancement in reduction of the development residues.

<Synthesis of Polymer>

The polymer (A) can be synthesized by polymerizing a monomer that gives each structural unit, in an appropriate solvent, with use of a radical polymerization initiator or the like.

Examples of the radical polymerization initiator include: azo-based radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), and dimethyl 2,2′-azobisisobutyrate; and peroxide radical initiators such as benzoyl peroxide, t-butyl hydroperoxide and cumene hydroperoxide. Of these polymerization initiators, AIBN and dimethyl 2,2′-azobisisobutyrate are preferable, and AIBN is more preferable. As the radical polymerization initiator, one type can be used alone, or two or more types can be used in combination.

Examples of solvents for the polymerization include: alkanes such as n-pentane, n-hexane, n-heptane, n-octane, n-nonane and n-decane; cycloalkanes such as cyclohexane, cycloheptane, cyclooctane, decalin and norbornane; aromatic hydrocarbons such as benzene, toluene, xylene, ethylbenzene and cumene; halogenated hydrocarbons such as chlorobutanes, bromohexanes, dichloroethanes, hexamethylene dibromide and chlorobenzene; saturated carboxylic acid esters such as ethyl acetate, n-butyl acetate, i-butyl acetate and methyl propionate; ketones such as acetone, butanone, 4-methyl-2-pentanone and 2-heptanone; ethers such as tetrahydrofuran, dimethoxyethane and diethoxyethane; and alcohols such as methanol, ethanol, 1-propanol, 2-propanol, and 4-methyl-2-pentanol. One type of the solvents may be used alone or two or more types of the solvents may be used in combination for the polymerizations.

A reaction temperature in the polymerization is preferably 40° C. or more, more preferably 50° C. or more. The reaction temperature is preferably 150° C. or less, more preferably 120° C. or less. A reaction time in the polymerization is preferably 1 hour or more, more preferably 2 hours or more. The reaction time is preferably 48 hours or less, more preferably 24 hours or less.

A weight average molecular weight (Mw) of the polymer (A) in terms of polystyrene by gel permeation chromatography (GPC) is preferably 1,000 or more, more preferably 2,000 or more, still more preferably 3,000 or more, and particularly preferably 5,000 or more. The Mw is preferably 50,000 or less, more preferably 30,000 or less, still more preferably 20,000 or less, and particularly preferably 10,000 or less. It is preferable to set the Mw of the polymer (A) in the range described above to enhance coating properties of the composition and to sufficiently suppress the development defects.

A ratio (Mw/Mn) of Mw to a number average molecular weight (Mn) in terms of polystyrene of the polymer (A) by GPC is preferably 5.0 or less, more preferably 3.0 or less, and still more preferably 2.0 or less. The Mw/Mn is usually 1 or more, and is preferably 1.3 or more.

<Acid Generator (B)>

The acid generator (B) is typically a substance that includes a radiation-sensitive onium cation and an organic anion. The acid generator (B) may be a low-molecular compound or may also be a polymer (provided that the polymer (A) is excluded).

Specific examples of the case where the acid generator (B) is a low-molecular-weight compound include the following onium salts [LB1] and [LB2] listed below.

[LB1] An onium salt that consists of a radiation-sensitive onium cation having two or more substituents β and an organic anion.

[LB2] An onium salt that consists of the other organic cation and an organic anion.

Specific Cation Structure [X]

In the onium salt [LB1], examples of the specific cation structure [X] include: a radiation-sensitive onium cation having the partial structure represented by the formula (1); and a radiation-sensitive onium cation having the partial structure represented by the formula (2). Specific examples of these radiation-sensitive onium cations include the radiation-sensitive onium cations in the examples in the description of the formula (1) and formula (2).

Other Organic Cations

In the onium salt [LB2], the other organic cation may be a radiation-sensitive onium cation that does not have the substituent β or has only one substituent β, and the structure is not particularly limited. To improve the lithographic properties of the composition, the other cations each preferably have a sulfonium cation structure or an iodonium cation structure. Specific examples include an organic cation represented by formula (4), an organic cation represented by formula (5), and an organic cation represented by formula (6).

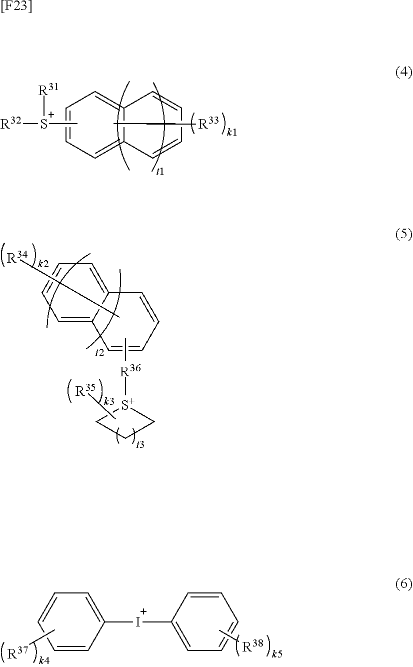

(In formula (4), R³¹ and R³² each independently represent a monovalent organic group having 1 to 20 carbon atoms; and k1 represents an integer of 0 to 5; when k1 is 1, R³³ is a monovalent organic group having 1 to 20 carbon atoms, a hydroxy group, a nitro group or a halogen group; when k1 is 2 or more, a plurality of R³³ are the same or different, and are each a monovalent organic group having 1 to 20 carbon atoms, a hydroxy group, a nitro group or a halogen group, or two or more of the plurality of R³³ taken together represent one part of a ring structure having 4 to 20 ring members together with carbon chains to which two or more of the plurality of R³³ bond; t1 is 0 or 1; and the number of the substituent β is 0 or 1.

In formula (5), k2 is an integer of 0 to 7; when k2 is 1, R³⁴ is a monovalent organic group having 1 to 20 carbon atoms, a hydroxy group, a nitro group or a halogen group; when k2 is 2 or more, a plurality of R³⁴ are the same or different, and are each a monovalent organic group having 1 to 20 carbon atoms, a hydroxy group, a nitro group or a halogen group, or two or more of the plurality of R³⁴ taken together represent one part of a ring structure having 4 to 20 ring members together with carbon chains to which two or more of the plurality of R³⁴ bond; k3 is an integer of 0 to 6; when k3 is 1, R³⁵ is a monovalent organic group having 1 to 20 carbon atoms, a hydroxy group, a nitro group or a halogen group; when k3 is 2 or more, a plurality of R³⁵ are the same or different, and are each a monovalent organic group having 1 to 20 carbon atoms, a hydroxy group, a nitro group or a halogen group, or two or more of the plurality of R³⁵ taken together represent one part of a ring structure having 4 to 20 ring members together with carbon chains to which two or more of the plurality of R³⁵ bond; t3 is an integer of 0 to 3; R³⁶ is a single bond or a divalent organic group having 1 to 20 carbon atoms; t2 is 0 or 1; and the number of the substituent β is 0 or 1.

In formula (6), k4 represents an integer of 0 to 5; when k4 is 1, R³⁷ is a monovalent organic group having 1 to 20 carbon atoms, a hydroxy group, a nitro group or a halogen group; when k4 is 2 or more a plurality of R³⁷ are the same or different, and are each a monovalent organic group having 1 to 20 carbon atoms, a hydroxy group, a nitro group or a halogen group, or two or more of the plurality of R³⁷ taken together represent one part of a ring structure having 4 to 20 ring members together with carbon chains to which two or more of the plurality of R³⁷ bond; k5 represents an integer of 0 to 5; when k5 is 1, R³⁸ is a monovalent organic group having 1 to 20 carbon atoms, a hydroxy group, a nitro group or a halogen group; when k5 is 2 or more, a plurality of R³⁸ are the same or different, and are each a monovalent organic group having 1 to 20 carbon atoms, a hydroxy group, a nitro group or a halogen group, or two or more of the plurality of R³⁸ taken together represent one part of a ring structure having 4 to 20 ring members together with carbon chains to which two or more of the plurality of R³⁸ bond; and the number of the substituent S is 0 or 1.)

In the formula (4), monovalent organic groups each having 1 to 20 carbon atoms represented by R³¹, R³² and R³³ are each preferably a monovalent hydrocarbon group having 1 to 20 carbon atoms, or a hydrocarbon group having 1 to 20 carbon atoms in which a hydrogen atom is substituted with a substituent, are each more preferably a monovalent aromatic hydrocarbon group having 6 to 18 carbon atoms, or a monovalent aromatic hydrocarbon group having 6 to 20 carbon atoms in which a hydrogen atom is substituted with a substituent, and are each further preferably a substituted or unsubstituted phenyl group. Examples of the monovalent hydrocarbon groups having 1 to 20 carbon atoms represented by R³¹, R³² and R³³ include groups the same as the examples of the monovalent hydrocarbon groups having 1 to 20 carbon atoms represented by R¹³ to R¹⁵ and R¹⁷ to R¹⁹ in the formula (iii-1) and formula (iii-2).

Examples of the substituents included in the groups represented by R³¹, R³² and R³³ include groups the same as the examples of the monovalent substituents represented by R^{4a}, R^{5a}, R^{6a}, R^{9a} and R^{10a} in the formula (1) and formula (2). k1 is preferably an integer of 0 to 2, more preferably 0 or 1, and still more preferably 0. t1 is preferably 0.

R³⁴ and R³⁵ in the formula (5) are preferably a substituted or unsubstituted monovalent hydrocarbon group having 1 to 20 carbon atoms, —OR^{k}, —COOR^{k}, —O—CO—R^{k}, —O—R^{kk}—COOR^{k}, or —R^{kk}—CO—R^{k}. R^{k} is a monovalent hydrocarbon group having 1 to 10 carbon atoms. R^{kk} is a single bond or a divalent hydrocarbon group having 1 to 10 carbon atoms. Examples of the monovalent hydrocarbon groups having 1 to 20 carbon atoms represented by R³⁴ and R³⁵ include groups the same as the examples of the monovalent hydrocarbon groups having 1 to 20 carbon atoms represented by R¹³ to R¹⁵ and R¹⁷ to R¹⁹ in the formula (iii-1) and formula (iii-2). In R³⁴ and R³⁵, examples of the substituent that substitutes for the hydrogen atom of the hydrocarbon group include groups the same as the examples of the substituents included in the groups represented by R³¹, R³² and R³³. Examples of the divalent organic group represented by R³⁶ include groups in which one hydrogen atom has been removed from the monovalent organic group having 1 to 20 carbon atoms in the examples of R³⁴ and R³⁵. k3 is preferably an integer of 0 to 2, more preferably 0 or 1, and still more preferably 0. t2 is preferably 0. t3 is preferably 2 or 3, and more preferably 2.

R³⁷ and R³⁸ in the formula (6) are preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k}, or —S—R^{k} or a ring structure that is taken together of two or more of the groups listed above. R^{k} and R^{kk} may be defined in the same way as R^{k} and R^{kk} of the group represented by R³⁴ and R³⁵, respectively. Examples of the monovalent hydrocarbon group having 1 to 20 carbon atoms represented by R³⁷ and R³⁸ include groups the same as the examples of the monovalent hydrocarbon group having 1 to 20 carbon atoms represented by R¹³ to R¹⁵ and R¹⁷ to R¹⁹ in the formula (iii-1) and formula (iii-2). In R³⁷ and R³⁸, examples of the substituent that substitutes for the hydrogen atom included in the hydrocarbon group include groups the same as the examples of the groups the substituents of the groups represented by R³¹, R³² and R³³. k4 and k5 are each preferably an integer of 0 to 2, more preferably 0 or 1, and still more preferably 0.

In the above, the other organic cations are preferably the radiation-sensitive onium cation represented by the formula (4) and the radiation-sensitive onium cation represented by the formula (6), and are more preferably the radiation-sensitive onium cation having a triarylsulfonium cation structure or a diaryliodonium cation structure. Specifically, it is particularly preferable for the other organic cation to be a radiation-sensitive onium cation that satisfies a1+a2+a3≤1 in the formula (1), and a radiation-sensitive onium cation that satisfies a7+a8≤1 in the formula (2) (provided that “*” in the formula (1) and formula (2) represents a bonding hand with a hydrogen atom), from the viewpoint of improving the lithographic properties of the composition.

Organic Anions

In the onium salts [LB1] and [LB2], examples of the organic anion include, but not limited to, organic anions each having a sulfonate anion structure, an imide anion structure, or a methide anion structure. Of these structures, the organic anions each having the sulfonate anion structure are preferable for the organic anions. Specifically, as the organic anions in the acid generator (B), organic anions represented by formula (7) can be preferably used.

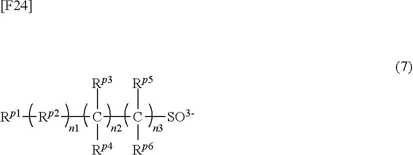

(In formula (7), n1 is an integer of 0 to 10; n2 is an integer of 0 to 10; n3 is an integer of 1 to 10; n1+n2+n3 is 1 to 30; when the n1 is 2 or more, a plurality of R^{p2} are the same or different; when the n2 is 2 or more, a plurality of R^{p3} are the same or different, and a plurality of R^{p4} are the same or different; when the n3 is 2 or more, a plurality of R^{p5} are the same or different, and a plurality of R^{p6} are the same or different; R^{p1} is a monovalent group containing a ring structure having 5 or more ring members; R^{p2} is a divalent linking group; R^{p3} and R^{p4} are each independently a hydrogen atom, a fluoro group, a monovalent hydrocarbon group having 1 to 20 carbon atoms, or a monovalent fluorinated hydrocarbon group having 1 to 20 carbon atoms; R^{p5} and R^{p6} are each independently a hydrogen atom, a fluoro group, or a monovalent fluorinated hydrocarbon group having 1 to 20 carbon atoms; and when the n3 is 1, the R^{p5} and R^{p6} are not both hydrogen atoms, and when the n3 is 2 or more, a plurality of R^{p5} and R^{p6} are not all hydrogen atoms.)

In the formula (7), examples of the monovalent groups that include the ring structure having 5 or more ring members represented by R^{p1} include a monovalent group including an alicyclic structure having 5 or more ring members, a monovalent group including an aliphatic heterocyclic structure having 5 or more ring members, a monovalent group including an aromatic ring structure having 5 or more ring members, and a monovalent group including an aromatic heterocyclic structure having 5 or more ring members.

Examples of the alicyclic structures having 5 or more ring members include: monocyclic cycloalkane structures such as a cyclopentane structure, a cyclohexane structure, a cycloheptane structure, a cyclooctane structure, a cyclononane structure, a cyclodecane structure, and a cyclododecane structure; monocyclic cycloalkene structures such as a cyclopentene structure, a cyclohexene structure, a cycloheptene structure, a cyclooctene structure, and a cyclodecene structure; polycyclic cycloalkane structures such as a norbornane structure, an adamantane structure, a tricyclodecane structure, and a tetracyclododecane structure; and polycyclic cycloalkene structures such as a norbornene structure and a tri-cyclodecene structure.

Examples of the aliphatic heterocyclic structures having 5 or more ring members include lactone structures such as a hexanolactone structure and a norbornane lactone structure; sultone structures such as a hexanosultone structure and a norbornane sultone structure; oxygen atom-containing heterocyclic structures such as an oxacycloheptane structure, an oxanorbornane structure, and a cyclic acetal structure; nitrogen atom-containing heterocyclic structures such as an azacyclohexane structure and a diazabicyclooctane structure; and sulfur atom-containing heterocyclic structures such as a thiacyclohexane structure and a thianorbornane structure.

Examples of the aromatic ring structures having 5 or more ring members include a benzene structure, a naphthalene structure, a phenanthrene structure, and an anthracene structure.

Examples of the aromatic heterocyclic structures having 5 or more ring members include: oxygen atom-containing heterocyclic structures such as a furan structure, a pyrane structure, and a benzopyran structure; and nitrogen atom-containing heterocyclic structures such as a pyridine structure, a pyrimidine structure, and an indole structure.

A part or all of the hydrogen atoms in the ring structure of R^{p1} may each be substituted with a substituent. Examples of the substituent include a fluoro group, a chloro group, a bromo group, an iodo group, a hydroxy group, a carboxy group, a cyano group, a nitro group, an alkoxy group, an alkoxycarbonyl group, an alkoxycarbonyloxy group, an acyl group, and an acyloxy group.

Of these examples, the monovalent group represented by R^{p1} is preferably a group having the aromatic ring structure having 5 or more ring members, and is particularly preferably a group having the benzene structure. The monovalent group represented by R^{p1} is preferably a group having an aromatic ring structure that is substituted with a halogen group, particularly preferably a group having an aromatic ring structure that is substituted with one or more iodo groups. In this case, in the monovalent group represented by R^{p1}, the number of the iodo groups bonded to the aromatic ring is further preferably two or more, particularly preferably three or more.

Examples of the divalent linking group represented by R^{p2} include a carbonyl group, an ether group, a carbonyloxy group, a sulfide group, a thiocarbonyl group, a sulfonyl group, and a divalent hydrocarbon group. Of these groups, the carbonyloxy group, the sulfonyl group, the alkanediyl group or the cycloalkanediyl group is preferable; the carbonyloxy group or the cycloalkanediyl group is more preferable; the carbonyloxy group or a norbornane-diyl group is still more preferable; and the carbonyloxy group is particularly preferable.

Examples of the monovalent hydrocarbon groups having 1 to 20 carbon atoms represented by R^{p3} and R^{p4} include alkyl groups having 1 to 20 carbon atoms. Examples of the monovalent fluorinated hydrocarbon groups having 1 to 20 carbon atoms represented by R^{p3} and R^{p4} include fluorinated alkyl groups having 1 to 20 carbon atoms. R^{p3} and R^{p4} are each preferably a hydrogen atom, a fluoro group or a fluoroalkyl group, more preferably the fluoro group or a perfluoroalkyl group, and still more preferably the fluoro group or a trifluoromethyl group.

Examples of the monovalent fluorinated hydrocarbon groups having 1 to 20 carbon atoms represented by R^{p5} and R^{p6} include fluoroalkyl groups having 1 to 20 carbon atoms. R^{p5} and R^{p6} are each preferably a fluoro group or a fluoroalkyl group, more preferably the fluoro group or a perfluoroalkyl group, still more preferably the fluoro group or a trifluoromethyl group, and further preferably the fluoro group. When n3 is 1, it is preferable that R^{p5} and R^{p6} are both the fluoro group, or that R^{p5} is the fluoro group and R^{p6} is the trifluoromethyl group.

n1 is preferably 0 to 5, more preferably 0 to 3, still more preferably 0 to 2, and particularly preferably 0 or 1. n2 is preferably 0 to 5, more preferably 0 to 2, still more preferably 0 or 1, and particularly preferably 0. n3 is preferably 1 to 5, more preferably 1 to 3, and still more preferably 1 or 2. When n3 is set in the range described above, the strength of the acid, which is generated from the acid generator (B), can be enhanced. As a result, the defect-suppressing property, the LWR performance and the sensitivity of the composition can be further enhanced. n1+n2+n3 is preferably 2 or more. The n1+n2+n3 is preferably 10 or less, more preferably 5 or less.

In the acid generator (B), the organic anions each preferably have a benzoyloxy group-containing sulfonium anion structure. Specifically, “R^{p1}—(R^{p2})ₙ₁—” in the formula (7) is preferably a structure represented by formula (7A). Specific examples of the monovalent substituent represented by R^{p7} in formula (7A) include groups the same as the examples of the substituents that may be included in the ring structure represented by R^{p1} in the formula (7).

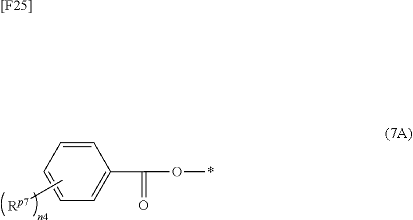

(In formula (7A), R^{p7} represents a monovalent substituent; n4 is an integer of 0 to 5; and “*” represents a bonding hand.)

Specific examples of the organic anion included in the acid generator (B) include organic anions represented by the following formulae. The organic anion included in the acid generator (B) is not limited to the following structures.

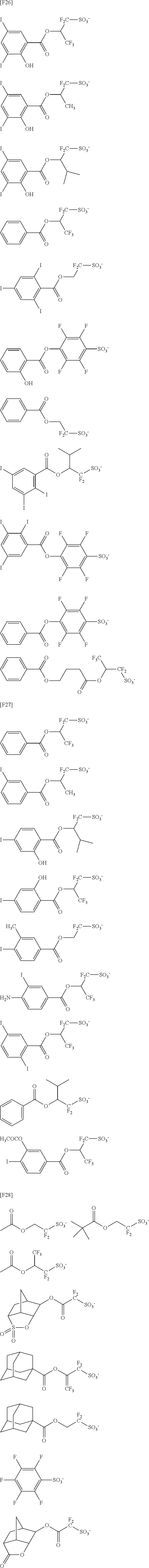

The onium salt [LB1] is preferably at least one selected from the group consisting of: compounds that each consist of a radiation-sensitive onium cation having a partial structure represented by the formula (1) and an organic anion; and compounds that each consist of a radiation-sensitive onium cation having a partial structure represented by the formula (2) and an organic anion.

Specific examples of the onium salt [LB2] include: a compound that consists of an organic cation represented by the formula (4) and an organic anion; a compound that consists of an organic cation represented by the formula (5) and an organic anion; and a compound that consists of an organic cation represented by the formula (6) and an organic anion.

When the acid generator (B) is a low-molecular-weight compound, a molecular weight of the acid generator (B) is preferably 1000 or less, more preferably 900 or less, still more preferably 800 or less, and further preferably 600 or less. When the acid generator (B) is a low-molecular-weight compound, a molecular weight of the acid generator (B) may be 100 or more, more preferably 150 or more.

When the acid generator (B) is a polymer, the polymer (hereinafter also referred to as “polymer (PB)”) is a polymer that includes the structural unit (IV). The polymer (PB) is distinguished from the polymer (A) in such a point as not to include the structural unit (I). Specific examples of the polymer (PB) include polymers [PB1] and [PB2] listed below.

[PB1] A polymer that consists of a radiation-sensitive onium cation having two or more substituents β and an organic anion, and has a structural unit derived from a monomer that either the radiation-sensitive onium cation or the organic anion has a group involved in the polymerization.

[PB2] A polymer that consists of the other organic cation and an organic anion, and has a structural unit derived from a monomer that either the other organic cation or the organic anion has a group involved in the polymerization.

Specific examples of the structural unit (IV) included in the polymer (PB) include structural units represented by the formula (iv-la) to formula (iv-9a), respectively.

The polymer (PB) may further include a structural unit different from the structural unit (IV). Examples of the structural unit include the structural units in the examples of the other structural units in the description of the polymer (A). The polymer (PB) can be synthesized by a method similar to the method of synthesizing the polymer (A).

A weight average molecular weight (Mw) of the polymer (PB) in terms of polystyrene by GPC is preferably 1,000 or more, is more preferably 2,000 or more, still more preferably 3,000 or more, and particularly preferably 5,000 or more. The Mw of the polymer (PB) is preferably 50,000 or less, more preferably 30,000 or less, still more preferably 20,000 or less, and particularly preferably 10,000 or less. A ratio (Mw/Mn) of Mw to a number average molecular weight (Mn) in terms of polystyrene of the polymer (PB) by GPC is preferably 5 or less, more preferably 3 or less, still more preferably 2 or less, and particularly preferably 1.7 or less. The Mw/Mn of the polymer (PB) is usually 1 or more, and is preferably 1.3 or more.

For the acid generator (B) in the composition, it is preferable to use low-molecular-weight compounds (specifically, the onium salts [LB1] to [LB2]). It is more preferable to include the onium salt [LB1].

A content ratio of the acid generator (B) in the composition is preferably 1% by mass or more, more preferably 2% by mass or more, and still more preferably 3% by mass or more, with respect to 100 parts by mass of the polymer (A). The content ratio of the acid generator (B) is preferably 30% by mass or less, more preferably 20% by mass or less, and still more preferably 15% by mass or less, with respect to 100 parts by mass of the polymer (A). It is preferable to set the content ratio of the acid generator (B) in the range described above to further enhance the defect-suppressing property, the LWR performance and the sensitivity of the composition. For the acid generator (B), one type may be used alone, or two or more types may be used in combination.

<Acid Diffusion Controller (C)>

The acid diffusion controller (C) is blended in the composition to suppress diffusion of the acid, which has been generated from the acid generator (B) through exposure, in the resist film so that a chemical reaction in a non-exposed region is suppressed. It is preferable to blend the acid diffusion controller (C) to the composition further enhance the lithographic properties of the composition. Furthermore, variations in width of lines in the resist pattern, which may occur due to the fluctuation of the holding time between the exposure and the development treatment, can be suppressed, thus a radiation-sensitive composition with excellent process stability can be obtained.

Examples of the acid diffusion controller (C) include a nitrogen-containing compound and a photodegradable base. For the photodegradable base, a compound that generates an acid weaker than the acid generated from the acid generator (B) through the exposure may be used. Examples of the compound include compounds that generate a weak acid (preferably carboxylic acid), a sulfonic acid or a sulfonamide through the exposure. The magnitude of the acidity can be evaluated by an acid dissociation constant (pKa). The acid dissociation constant of the acid generated from the photodegradable base is usually −3 or more, preferably −1≤pKa≤7, and more preferably 0≤pKa≤5. The acid diffusion controller (C) is preferably a low-molecular-weight compound.

When the acid diffusion controller (C) in the examples of the composition containing the acid generator (B) and the acid diffusion controller (C) includes the photodegradable base, the acid generator (B) corresponds to the “first acid-generating body” and the photodegradable base corresponds to the “second acid-generating body”.

Nitrogen-Containing Compounds

Examples of the nitrogen-containing compounds include: a compound represented by formula (8) (hereinafter also referred to as “nitrogen-containing compound (8A)”); a compound having two nitrogen atoms (hereinafter also referred to as “nitrogen-containing compound (8B)”); a compound having three nitrogen atoms (hereinafter also referred to as “nitrogen-containing compound (8C)”); an amide group-containing compound; a urea compound; a nitrogen-containing heterocyclic compound; and a nitrogen-containing compound having an acid-dissociable group.

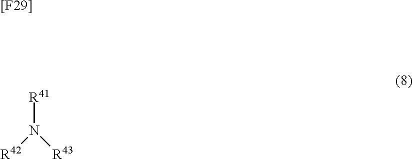

(In formula (8), R⁴¹, R⁴² and R⁴³ each independently represent a hydrogen atom, a substituted or unsubstituted alkyl group, a substituted or unsubstituted cycloalkyl group, a substituted or unsubstituted aryl group, or a substituted or unsubstituted aralkyl group.)

For specific examples of the nitrogen-containing compounds, the nitrogen-containing compound (8A) include: monoalkylamines such as n-hexylamine; dialkylamines such as di-n-butylamine; trialkylamines such as triethylamine and tri-n-pentylamine; and aromatic amines such as aniline and 2,6-diisopropylaniline.

Examples of the nitrogen-containing compound (8B) include ethylenediamine and N,N,N′,N′-tetramethylethylenediamine.

Examples of the nitrogen-containing compound (8C) include: polyamine compounds such as polyethyleneimine and polyallylamine; and polymers such as dimethylaminoethyl acrylamide.

Examples of the amide group-containing compound include formamide, N-methylformamide, N,N-dimethylformamide, acetamide, N-methylacetamide, N,N-dimethylacetamide, propionamide, benzamide, pyrrolidone and N-methylpyrrolidone.

Examples of the urea compound include urea, methylurea, 1,1-dimethylurea, 1,3-dimethylurea, 1,1,3,3-tetramethylurea, 1,3-diphenylurea and tributylthiourea.

Examples of the nitrogen-containing heterocyclic compound include: pyridines such as pyridine and 2-methylpyridine; morpholines such as N-propylmorpholine, N-(undecane-1-ylcarbonyloxyethyl)morpholine; and pyrazine and pyrazole.

Examples of the nitrogen-containing compounds each having an acid-dissociable group include N-t-butoxycarbonyl piperidine, N-t-butoxycarbonyl imidazole, N-t-butoxycarbonyl benzimidazole, N-t-butoxycarbonyl-2-phenyl benzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, and N-t-amyloxycarbonyl-4-hydroxypiperidine.

The nitrogen-containing compound as the acid diffusion controller (C) is preferably at least one type selected from the group consisting of the nitrogen-containing compound (8A) and the nitrogen-containing heterocyclic compound, more preferably at least one type selected from the group consisting of trialkylamines, aromatic amines and morpholines, and still more preferably at least one type selected from the group consisting of tri-n-pentylamine, 2,6-diisopropyl aniline and N-(undecane-1-ylcarbonyloxyethyl) morpholine.

Photodegradable Bases

The photodegradable base is preferably a compound that generates an acid through irradiation of radioactive rays, where the acid does not substantially dissociate an acid-dissociable group in the composition when heated at 110° C. for 1 minute. The photodegradable base is typically a compound in which an acid generated through the exposure does not cause or hardly causes a dissociation reaction of the acid-dissociable group under use conditions.

For the photodegradable base, an onium salt that generates a carboxylic acid, a sulfonic acid or sulfonamide through irradiation of radioactive rays can be preferably used. Preferable specific examples of the photodegradable base include onium salt compounds represented by formula (9). [F30]

E⁻Z⁺ (9)

(In formula (9), E⁻ represents an organic anion represented by R⁵¹—COO—, R⁵²—SO₂—N⁻—R⁵¹ or R⁵¹—SO₃—; R⁵¹ and R⁵² each independently represent a monovalent organic group having 1 to 30 carbon atoms; when E⁻ is an organic anion represented by R⁵¹—SO₃—, a fluorine atom is not bonded to a carbon atom to which SO₃— is bonded; and Z⁺ represents a radiation-sensitive onium cation.)

Examples of the monovalent organic group having 1 to 30 carbon atoms represented by R⁵¹ in the formula (9) include: a monovalent hydrocarbon group having 1 to 30 carbon atoms; a monovalent group 7 having 1 to 30 carbon atoms and having a divalent heteroatom-containing group in between carbon and carbon of the hydrocarbon group or at a terminal adjacent to a bonding hand; and a monovalent group in which at least one hydrogen atom of the hydrocarbon group or the monovalent group γ is substituted with a monovalent heteroatom-containing group. Specific examples of these groups include groups the same as the monovalent organic groups represented by R³¹, R³² and R³³ in the formula (4). The monovalent organic group having 1 to 30 carbon atoms represented by R⁵¹ is preferably a monovalent group having a substituted or unsubstituted aromatic ring. The group represented by R⁵¹ may include a partial structure represented by the formula (7A).

Examples of the monovalent organic group having 1 to 30 carbon atoms represented by R⁵² include a substituted or unsubstituted alkyl group and a substituted or unsubstituted cycloalkyl group. Examples of the substituent in the substituted alkyl group include a fluoro group. Examples of the substituent in the substituted cycloalkyl group include an alkyl group having 1 to 10 carbon atoms, a fluoro group and an iodo group.

The radiation-sensitive onium cation represented by Z⁺ is preferably an organic cation represented by the formula (Y-1) or formula (Y-2). The radiation-sensitive onium cation represented by Z⁺ may have the specific cation structure [X], or may be another organic cation. Specific examples of the photodegradable base include onium salts [C1] and [C2] listed below.

[C1] An onium salt that consists of a radiation-sensitive onium cation having two or more substituents β and an organic anion.

[C2] An onium salt that consists of the other organic cation and an organic anion.

Examples of the radiation-sensitive onium cation having two or more of the substituents β in the onium salt [C1] include: a radiation-sensitive onium cation having the partial structure represented by the formula (1); and a radiation-sensitive onium cation having the partial structure represented by the formula (2). Examples of the other organic cation include an onium cation represented by the formula (4), an onium cation represented by the formula (5), and an onium cation represented by the formula (6).

The organic anion included in the photodegradable base preferably has a carboxylate anion structure or a sulfonate anion structure. Specific examples of the organic anions include organic anions represented by the following formulae. The organic anion included in the photodegradable base is not limited to the following structures.

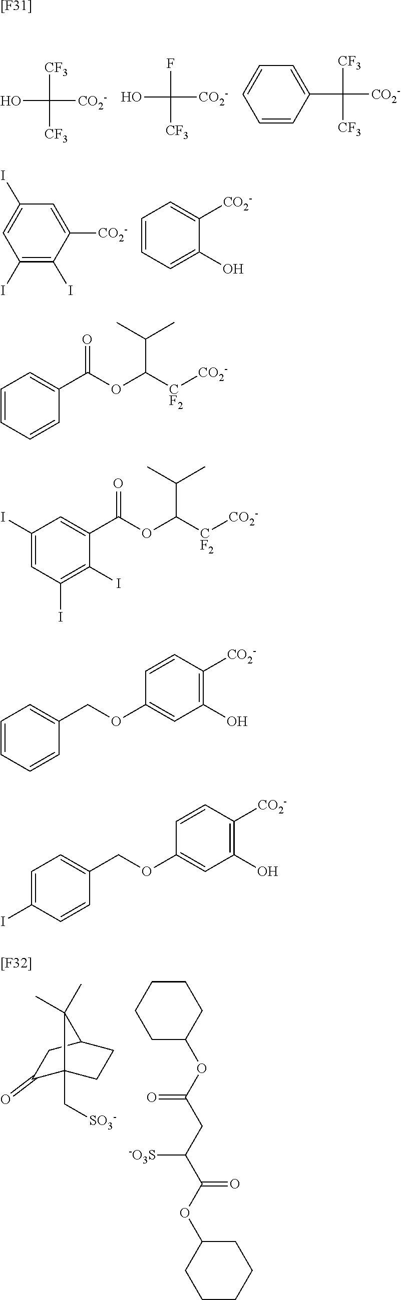

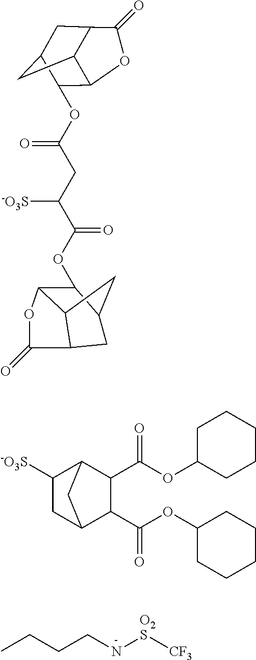

Specific examples of the onium salt [C1] include: compounds that each include a radiation-sensitive onium cation having a partial structure represented by the formula (1) and a carboxylate anion or a sulfonate anion; and compounds that each include a radiation-sensitive onium cation having a partial structure represented by the formula (2) and a carboxylate anion or a sulfonate anion. Specific examples of the onium salt [C2] include: compounds that each include an organic cation represented by the formula (4) and a carboxylate anion or a sulfonate anion; compounds that each include an organic cation represented by the formula (5) and a carboxylate anion or a sulfonate anion; and compounds that each include an organic cation represented by the formula (6) and a carboxylate anion or a sulfonate anion.

A molecular weight of the acid diffusion controller (C) is preferably 1000 or less, more preferably 900 or less, still more preferably 800 or less, and further preferably 600 or less. The molecular weight of the acid diffusion controller (C) may be 100 or more, preferably 150 or more.

When the composition contains the acid diffusion controller (C), a content ratio of the acid diffusion controller (C) in the composition is preferably 0.1% by mass or more, more preferably 1% by mass or more, and still more preferably 3% by mass or more, with respect to 100 parts by mass of the polymer (A). The content ratio of the acid diffusion controller (C) is preferably 20% by mass or less, more preferably 15% by mass or less, and still more preferably 10% by mass or less, with respect to 100 parts by mass of the polymer (A). It is preferable to set the content ratio of the acid diffusion controller (C) in the range described above to further enhance the LWR performance of the composition. For the acid diffusion controller (C), one type may be used alone, or two or more types may be used in combination.

The ratio of the acid-generating compound contained in the composition (specifically, a ratio of the total of the acid generator (B) and the acid diffusion controller (C)) is preferably 1% by mass or more, more preferably 2% by mass or more, still more preferably 3% by mass or more, and further preferably 5% by mass or more, with respect to the total amount of the solid content contained in the composition. The ratio of the acid-generating compound is preferably 20% by mass or less, more preferably 15% by mass or less, still more preferably 10% by mass or less, and further preferably 8% by mass or more, with respect to the total amount of the solid content contained in the composition. It is preferable to set the content ratio of the acid-generating compound in the range described above to improve the lithographic properties such as the LWR performance and CDU performance of the composition.

In the composition, a ratio of the specific cation structure [X] in the radiation-sensitive onium cation structure included in the acid-generating compound is preferably 10 mol % or more, more preferably 20 mol % or more, still more preferably 50 mol % or more, and further preferably 70 mol % or more. It is preferable to set a ratio of the specific cation structure [X] to the radiation-sensitive onium cation included in the acid-generating compound in the range described above to obtain sufficient effect of sensitivity enhancement, CDU performance enhancement of the composition and enhancement in reduction of the development residues.

<Solvent (D)>

The solvent (D) is not particularly limited as long as the solvent can dissolve or disperse the polymer (A), the acid generator (B), and the acid diffusion controller (C) and the like that is optionally contained. Examples of the solvent (D) include alcohols, ethers, ketones, amides, esters and hydrocarbons.

Examples of the alcohols include: aliphatic monoalcohols each having 1 to 18 carbon atoms such as 4-methyl-2-pentanol and n-hexanol; alicyclic monoalcohols each having 3 to 18 carbon atoms such as cyclohexanol; polyhydric alcohols each having 2 to 18 carbon atoms such as 1,2-propylene glycol; and polyhydric alcohol partial ethers each having 3 to 19 carbon atoms such as propylene glycol monomethyl ether. Examples of the ethers include: dialkyl ethers such as diethyl ether, dipropyl ether, dibutyl ether, dipentyl ether, diisoamyl ether, dihexyl ether and diheptyl ether; cyclic ethers such as tetrahydrofuran and tetrahydropyran; and aromatic ring-containing ethers such as diphenyl ether and anisole.

Examples of the ketones include: chain ketones such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone and trimethylnonanone: cyclic ketones such as cyclopentanone, cyclohexanone, cycloheptanone, cyclooctanone and methylcyclohexanone: and 2,4-pentanedione, acetonylacetone, acetophenone and diacetone alcohol. Examples of the amides include: cyclic amides such as N,N′-dimethyl imidazolidinone and N-methylpyrrolidone; and chain amides such as N-methylformamide, N,N-dimethylformamide, N,N-diethylformamide, acetamide, N-methylacetamide, N,N-dimethylacetamide and N-methylpropionamide.

Examples of the esters include: monocarboxylic acid esters such as n-butyl acetate and ethyl lactate; polyhydric alcohol carboxylates such as propylene glycol acetate; polyhydric alcohol partial ether carboxylates such as propylene glycol monomethyl ether acetate; polyvalent carboxylic acid diesters such as diethyl oxalate; carbonates such as dimethyl carbonate and diethyl carbonate; and cyclic esters such as 7-butyrolactone. Examples of the hydrocarbons include: aliphatic hydrocarbons each having 5 to 12 carbon atoms such as n-pentane and n-hexane; and aromatic hydrocarbons each having 6 to 16 carbon atoms such as toluene and xylene.

It is preferable that the solvent (D) contains at least one type selected from the group consisting of the ester and the ketone, more preferably at least one type selected from the group consisting of the polyhydric alcohol partial ether carboxylate and the cyclic ketone. It is further preferable that the solvent (D) contains at least one type selected from the propylene glycol monomethyl ether acetate, the ethyl lactate and the cyclohexanone. For the solvent (D), one type or two or more types can be used.

<High Fluorine-Containing Polymer (E)>

The high fluorine-containing polymer (E) (hereinafter also simply referred to as “polymer (E)”) is a polymer that has a mass content of fluorine atoms greater than that of the polymer (A). The polymer (E) is contained in the composition, for example, as a water repellent additive. The polymer (E) is distinguished from the polymer (A) in such a point as not to include the structural unit (I).

The fluorine atom content of the polymer (E) is not particularly limited as long as the content is greater than the content of the polymer (A). The fluorine atom content of the polymer (E) is preferably 1% by mass or more, more preferably 2% by mass or more, still more preferably 4% by mass or more, and particularly preferably 7% by mass or more. The fluorine atom content of the polymer (E) is preferably 60% by mass or less, more preferably 40% by mass or less, and still more preferably 30% by mass or less. The fluorine atom content (% by mass) of the polymer can be calculated from the structure of the polymer, which has been obtained by ¹³C-NMR spectrum measurement or the like.

Examples of the structural unit in the polymer (E) include the following structural unit (Ea) and structural unit (Eb). The polymer (E) may include one type or two or more types of structural units (Ea) and one type or two or more types of structural units (Eb).

[Structural Unit (Ea)]

The structural unit (Ea) is a structural unit represented by formula (11a). With the structural unit (Ea), the fluorine atom content of the polymer (E) is adjustable.

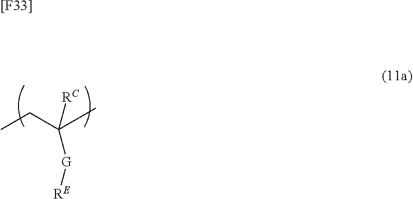

(In formula (11a), R^{C} represents a hydrogen atom, a fluoro group, a methyl group or a trifluoromethyl group; G represents a single bond, an oxygen atom, a sulfur atom, —CO—O—, —SO₂—O—NH—, —CO—NH— or —O—CO—NH—; and R^{E} represents a monovalent fluorinated chain hydrocarbon group having 1 to 6 carbon atoms, or a monovalent fluorinated alicyclic hydrocarbon group having 4 to 20 carbon atoms.

Examples of the monovalent fluorinated chain hydrocarbon group having 1 to 6 carbon atoms represented by R^{E} include a trifluoromethyl group, a 2,2,2-trifluoroethyl group, a perfluoroethyl group, a 2,2,3,3,3-pentafluoropropyl group, a 1,1,1,3,3,3-hexafluoropropyl group, a perfluoro n-propyl group, a perfluoroisopropyl group, a perfluoro n-butyl group, a perfluoroisobutyl group, a perfluoro t-butyl group, a 2,2,3,3,4,4,5,5-octafluoropentyl group, and a perfluorohexyl group.

Examples of the monovalent fluorinated alicyclic hydrocarbon group having 4 to 20 carbon atoms represented by R^{E} include a monofluorocyclopentyl group, a difluorocyclopentyl group, a perfluorocyclopentyl group, a monofluorocyclohexyl group, a difluorocyclohexyl group, a perfluorocyclohexylmethyl group, a fluoronorbornyl group, a fluoroadamantyl group, a fluorobornyl group, a fluoroisobornyl group, a fluorotricyclodecyl group, and a fluorotetracyclodecyl group.

Examples of a monomer that gives the structural unit (Ea) include a (meth)acrylic ester having a fluorinated chain hydrocarbon group and a (meth)acrylic ester having a fluorinated alicyclic hydrocarbon group. Specific examples of the (meth)acrylic ester having the fluorinated chain hydrocarbon group include: alkyl (meth)acrylic esters in each of which a straight chain moiety is fluorinated such as 2,2,2-trifluoroethyl (meth)acrylic ester; alkyl (meth)acrylic esters in each of which a branched chain moiety is fluorinated such as 1,1,1,3,3,3-hexafluoroisopropyl (meth)acrylic ester; straight chain perfluoroalkyl (meth)acrylic esters such as perfluoroethyl (meth)acrylic ester; and branched chain perfluoroalkyl (meth)acrylic esters such as perfluoroisopropyl (meth)acrylic ester.

Examples of the (meth)acrylic ester having the fluorinated alicyclic hydrocarbon group include: (meth)acrylic esters each having a monocyclic fluorinated alicyclic saturated hydrocarbon group such as perfluorocyclohexylmethyl (meth)acrylic ester, monofluorocyclopentyl (meth)acrylic ester, and perfluorocyclopentyl (meth)acrylic ester; and (meth)acrylic esters each having a polycyclic fluorinated alicyclic saturated hydrocarbon group such as fluoronorbornyl (meth)acrylic ester.

When the polymer (E) includes the structural unit (Ea), a content ratio of the structural unit (Ea) is preferably 5 mol % or more, more preferably 10 mol % or more, and still more preferably 20 mol % or more, with respect to all the structural units constituting the polymer (E).

[Structural Unit (Eb)]

The structural unit (Eb) is a structural unit represented by formula (11b). With the structural unit (Eb), the hydrophobicity is of the polymer (E) is enhanced. Accordingly, a dynamic contact angle of the surface of the resist film formed from the composition can be further enhanced.

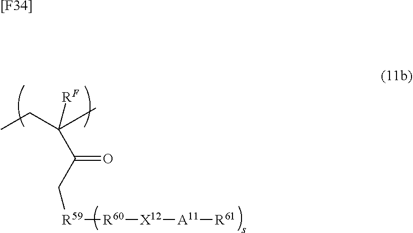

(In formula (11b), R^{F} represents a hydrogen atom, a fluoro group, a methyl group or a trifluoromethyl group; R⁵⁹ represents a (s+1)-valent hydrocarbon group having 1 to 20 carbon atoms, or a group in which an oxygen atom, a sulfur atom, —NR′—, a carbonyl group, —CO—O— or —CO—NH— is bonded to a terminal of the hydrocarbon group adjacent to R⁶⁰; R′ represents a hydrogen atom or a monovalent organic group; R⁶⁰ represents a single bond, a divalent chain hydrocarbon group having 1 to 10 carbon atoms, or a divalent alicyclic hydrocarbon group having 4 to 20 carbon atoms; X¹² represents a divalent fluorinated chain hydrocarbon group having 1 to 20 carbon atoms; A¹¹ represents an oxygen atom, —NR″-, —CO—O—* or —SO₂—O—*; R″ represents a hydrogen atom or a monovalent organic group; “*” represents a bonding site that is bonded to R⁶¹; R⁶¹ represents a hydrogen atom or a monovalent organic group; s represents an integer of 1 to 3; and when the s is 2 or 3, a plurality of R⁶⁰, X¹², A¹¹ and R⁶¹ are the same or different, respectively.)

It is preferable that R⁶¹ is a hydrogen atom to enhance the solubility of the polymer (E) in an alkali developer. Examples of the monovalent organic group represented by R⁶¹ include an acid-dissociable group, an alkali dissociable group, and a hydrocarbon group having 1 to 30 carbon atoms, which may include a substituent.

When the polymer (E) includes the structural unit (Eb), a content ratio of the structural unit (Eb) is preferably 5 mol % or more, more preferably 10 mol % or more, and still more preferably 20 mol % or more, with respect to all the structural units constituting the polymer (E).

The polymer (E) may include, other than the structural unit (Ea) and the structural unit (Eb), a structural unit that has an acid-dissociable group different from the structural unit (Ea) and the structural unit (Eb) (hereinafter also referred to as “structural unit (Ec)”). When the polymer (E) includes the structural unit (Ec), a resist pattern is obtained in a more proper shape. Examples of the structural unit (Ec) include the structural unit (I) and the structural unit (III) presented in the description of the polymer (A).

When the polymer (E) includes the structural unit (Ec), a content ratio of the structural unit (Ec) is preferably 5 mol % or more, more preferably 25 mol % or more, and still more preferably 50 mol % or more, with respect to all the structural units constituting the polymer (E). The content ratio of the structural unit (Ec) is preferably 90 mol % or less, more preferably 80 mol % or less, and still more preferably 70 mol % or less, with respect to all the structural units constituting the polymer (E).

The Mw of the polymer (E) by GPC is preferably 1,000 or more, more preferably 3,000 or more, and still more preferably 4,000 or more. The Mw of the polymer (E) is preferably 50,000 or less, more preferably 30,000 or less, and still more preferably 20,000 or less. A molecular weight distribution (Mw/Mn) of the polymer (E), which is expressed by a ratio of Mn to Mw by GPC, is usually 1 or more, preferably 1.2 or more. The Mw/Mn is preferably 5 or less, more preferably 3 or less.

When the composition contains the polymer (E), a content ratio of the polymer (E) in the composition is preferably 0.1 parts by mass or more, more preferably 1 part by mass or more, and still more preferably 2 parts by mass or more, with respect to 100 parts by mass of the polymer (A). The content ratio of the polymer (E) is preferably 20 parts by mass or less, more preferably 10 parts by mass or less, and still more preferably 7 parts by mass or less, with respect to 100 parts by mass of the polymer (A). The composition may contain one type of the polymer (E) alone or may contain a combination of two or more types.

<Other Optional Components>

The composition may further contain a component that is different from the polymer (A), the acid generator (B), the acid diffusion controller (C), the solvent (D), and the high fluorine-containing polymer (E) (hereinafter also referred to as “the other optional component”). Examples of the other optional components include a surface active agent, an alicyclic skeleton-containing compound (for example, 1-adamantanecarboxylic acid, 2-adamantanone, t-butyl deoxycholate), a sensitizer, and an uneven distribution promoter. A content ratio of the other optional components in the composition can be appropriately selected depending on the respective components within a scope not to impair the effect of the present disclosure.

<<Method for Producing Radiation-Sensitive Composition>>

The present composition can be produced, for example, by mixing components such as the polymer (A) and the acid generator (B), and, if necessary, the acid diffusion controller (C) and the solvent (D) at a desired ratio, and filtering the obtained mixture preferably with the use of a filter (for example, a filter having a pore size of about 0.2 μm). A solid content concentration of the composition is preferably 0.1% by mass or more, more preferably 0.5% by mass or more, and still more preferably 1% by mass or more. The solid content concentration of the composition is preferably 50% by mass or less, more preferably 20% by mass or less, and still more preferably 5% by mass or less. It is preferable to set the solid content concentration of the composition in the range described above to improve the coating property the shape of the resist pattern.

The composition obtained by the above method can be used as a composition for forming a positive pattern in which a pattern is formed with use of an alkali developer, or can be used also as a composition for forming a negative pattern for which a developer containing an organic solvent is used.

<<Method of Forming a Resist Pattern>>

A method of forming a resist pattern in the present disclosure includes: coating one surface of a substrate with the composition (hereinafter also referred to as “coating step”); exposing the resist film obtained in the coating step (hereinafter also referred to as “exposure step”); and developing the exposed resist film (hereinafter also referred to as “development step”). Examples of the pattern formed by the resist pattern of the present disclosure include a line and space pattern and a hole pattern. In the method of forming the resist pattern in the present disclosure, the resist film is formed with use of the composition. Accordingly, the resist patterns can be provided with excellent sensitivity, small CDU, and reduced development residues. Each step will be described below.

[Coating Step]

In the coating step, a resist film is formed on a substrate by coating one surface of the substrate with the composition. A known substrate may be used for the substrate on which the resist film is formed, for example, a silicon wafer, silicon dioxide, and a wafer coated with aluminum may be used. Alternatively, a substrate on which an organic or inorganic antireflection film is formed may be used. An example of such a film is disclosed in Japanese Unexamined Patent Publication No. H6-12452 or Japanese Laid-Open Patent Publication No. S59-93448. Examples of the coating method for the composition include rotation coating (spin coating), cast coating and roll coating. After the coating step, prebaking (PB) may be performed for volatilizing the solvent in the coating film. A PB temperature is preferably 60° C. or more, more preferably 80° C. or more. The PB temperature is preferably 140° C. or less, more preferably 120° C. or less. PB time is preferably 5 seconds or more, more preferably 10 seconds or more. The PB time is preferably 600 seconds or less, more preferably 300 seconds or less. An average thickness of the resist film to be formed is preferably 10 to 1,000 nm, more preferably 20 to 500 nm.

[Exposure Step]

In the exposure step, the resist film obtained in the coating step is exposed. The exposure is performed by irradiating the resist film with radioactive rays through a photomask, or in some cases, through an immersion medium such as water. Examples of the radioactive rays include: electromagnetic waves such as visible rays, ultraviolet rays, far-ultraviolet rays, extreme ultraviolet (EUV) rays, X-rays and γ-rays; and charged particle beams such as electron beams and α-rays, depending on a target line width of the pattern. For the radioactive rays applied to the resist film formed with use of the composition are preferably the far-ultraviolet ray, the EUV ray or the electron beam, more preferably ArF excimer laser light (wavelength of 193 nm), KrF excimer laser light (wavelength of 248 nm), the EUV or the electron beam, further more preferably the ArF excimer laser light, the EUV or the electron beam, still more preferably the EUV or the electron beam, and is particularly preferably the EUV.

After the exposure, it is preferable to perform post-exposure baking (PEB). With the PEB, dissociation of the acid-dissociable group by the acid generated from the acid-generating compound through the exposure may be promoted in the exposed portion of the resist film. Therefore, the difference in the solubility in the developer between the exposed portion and the unexposed portion may increase. A PEB temperature is preferably 50° C. or more, more preferably 80° C. or more. The PEB temperature is preferably 180° C. or less, more preferably 130° C. or less. PEB time is preferably 5 seconds or more, more preferably 10 seconds or more. The PEB time of the PEB is preferably 600 seconds or less, more preferably 300 seconds or less.

[Development Step]

In the development step, the exposed resist film is developed. Through the step, a designed resist pattern is formed. After the development, washing of the film with a rinsing liquid such as water and alcohol and drying of the film are usually performed. A development method used in the developing step may be alkali developing or organic solvent developing.

The developer for the alkali developing may be an alkaline aqueous solution in which at least one type of alkaline compounds is dissolved. Examples of the alkaline compounds include: sodium hydroxide; potassium hydroxide; sodium carbonate; sodium citrate; sodium methacrylate; ammonia water; ethylamine; n-propylamine; diethylamine; di-n-propylamine; triethylamine; methyl diethylamine; ethyl dimethylamine; triethanolamine; tetramethyl ammonium hydroxide (TMAH); pyrrole; piperidine; choline; 1,8-diazabicyclo-[5.4.0]-7-undecene; and 1,5-diazabicyclo-[4.3.0]-5-nonene. A TMAH aqueous solution is preferable and a 2.38% by mass TMAH aqueous solution is more preferable.

The developer for the organic solvent developing may be one or two or more types of various organic solvents (for example, hydrocarbons, ethers, esters, ketones, alcohols). Specific examples of the organic solvent for the developer include the solvents in the examples of the solvent (D) in the description of the composition. The esters and the ketones are preferable for the developer in the organic solvent developing. Among the esters, acetate esters are preferable, and n-butyl acetate is more preferable. Among the ketones, chain ketones are preferable, and 2-heptanone is more preferable. In the developer, a content ratio of the organic solvent is preferably 80% by mass or more, more preferably 90% by mass or more, still more preferably 95% by mass or more, and particularly preferably 99% by mass or more. Examples of components other than the organic solvent in the developer include water and silicon oil.

Examples of the development method include: a method that includes immersing a substrate in a tank filled with the developer for a certain period of time (dipping method); a method that includes building a puddle of the developer on a surface of a substrate by a surface tension and holding the buddle still for a certain period of time for the development (puddle method); a method that includes spraying a developer onto a surface of the substrate (spray method); and a method that includes continuously discharging the developer onto a substrate rotating at a constant speed while scanning a developer discharge nozzle at a constant speed (dynamic dispensing method).

### EXAMPLES

The present disclosure will be specifically described below on the basis of Examples, and the present disclosure is not limited to these examples. Methods of measuring physical values will be described.

[Weight Average Molecular Weight and Number Average Molecular Weight]

The weight average molecular weight (Mw) and the number average molecular weight (Mn) of the polymers were measured by gel permeation chromatography (GPC). The measurement was conducted under the following conditions using GPC columns (2 pieces of “G2000HXL”, one piece “G3000HXL” and one piece of “G4000HXL”) manufactured by Tosoh Corporation.
Eluent: tetrahydrofuran (FUJIFILM Wako Pure Chemical Corporation)
Flow rate: 1.0 mL/min
Sample concentration: 1.0% by mass
Injected sample amount: 100 μL
Column temperature: 40° C.
Detector: differential refractometer
Standard material: monodisperse polystyrene

[¹H-NMR]

A ¹H-NMR analysis was performed with use of a nuclear magnetic resonance apparatus (“JNM-ECZS400” manufactured by JEOL Ltd.).

The structures of the radiation-sensitive acid generator (PAG), the acid diffusion controller, and the high fluorine-containing resin, which were used in the preparation of the radiation-sensitive resin composition, are presented below.

[Radiation-Sensitive Acid Generator (PAG)]

Structures of the radiation-sensitive acid generators (PAG1 to PAG9) used in the following Examples are as follows. PAG1 to PAG9 were each synthesized by ion exchange between an ammonium salt of a sulfonic acid which gives an organic acid anion moiety and a sulfonium chloride or iodonium chloride which gives an onium cation moiety. PAG1 to PAG3, and PAG5 to PAG8 are radiation-sensitive acid generators having the specific cation structure [X]. For example, the number of the substituents (3 of PAG1 is two and the number of the substituents (3 of PAG8 is three.

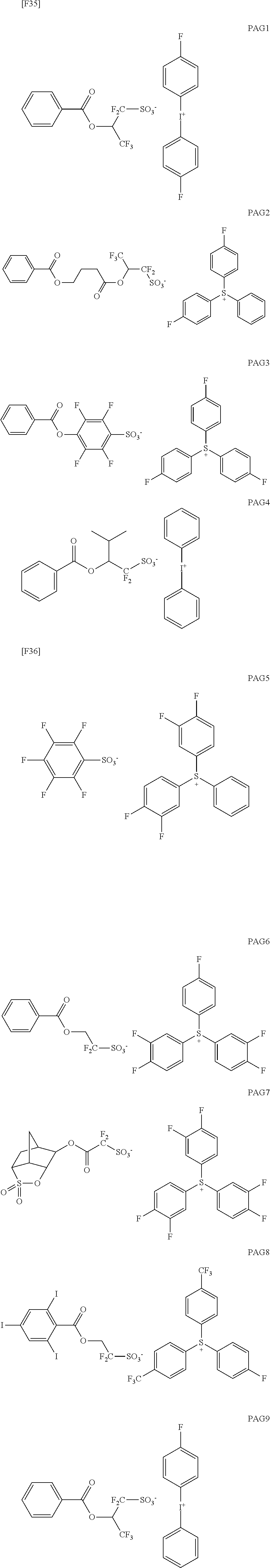

[Acid Diffusion Controller]

Structures of the acid diffusion controllers (Q-1 to Q-7) used in the following Examples are as follows. Q-2 and Q-4 are acid diffusion controllers having the specific cation structure [X].

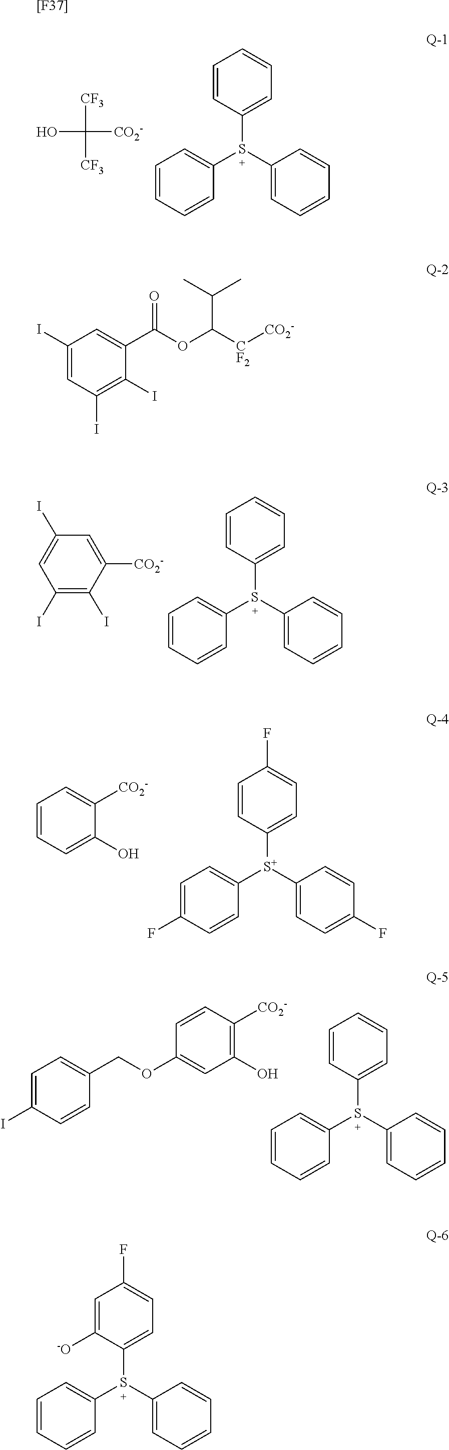

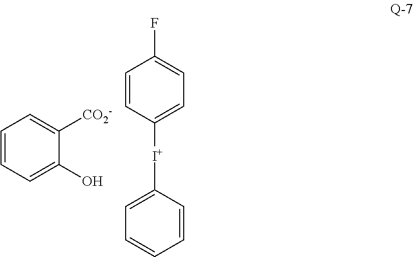

[High Fluorine-Containing Resin]

Structures and physical properties of the high fluorine-containing resin (F-1) used in the following Examples are as follows.

F-1: Mw=8,900, Mw/Mn=2.0

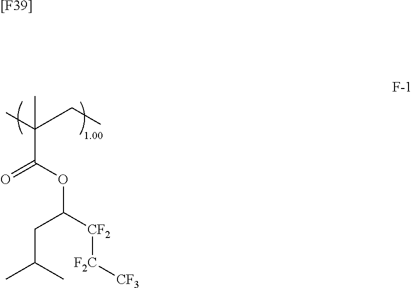

[Synthesis of Base Resins (P-1 to P-5)]

Each monomer was combined with each other, and was copolymerized in tetrahydrofuran (THF) solvent. The products were crystallized in methanol, the resultant products were further repeatedly washed with hexane, and then were isolated and dried. Thereby, a polymer P-1 to a polymer P-5 were obtained as polymers (referred to as “base resins”) having the following compositions (molar ratios). The compositions of the obtained base resins were confirmed by 1H-NMR, and the Mw and the dispersity (Mw/Mn) were confirmed by GPC (solvent: THF, and standard: polystyrene).
Polymer P-1: Mw=7,900, Mw/Mn=1.8
Polymer P-2: Mw 7,800, Mw/Mn=1.8
Polymer P-3: Mw=8,200, Mw/Mn=1.8
Polymer P-4: Mw=8,100, Mw/Mn=1.8
Polymer P-5: Mw=9,400, Mw/Mn=1.7

P-2 and P-3 are polymers having the specific cation structure [X].

(Compositions of Base Resin)

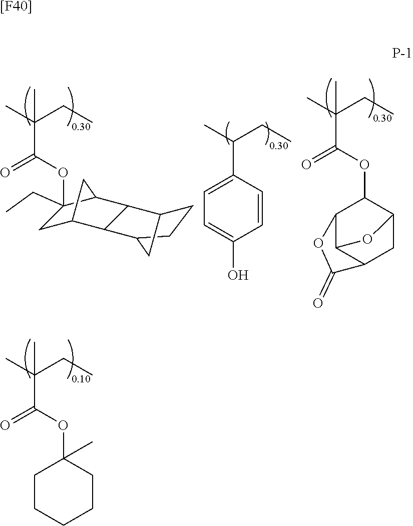

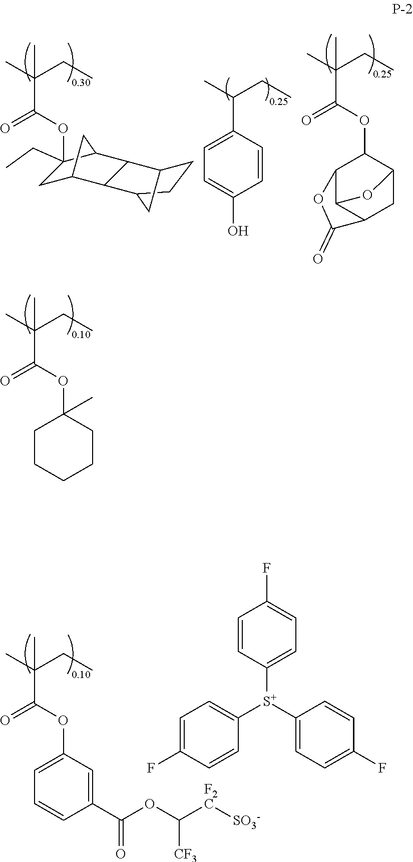

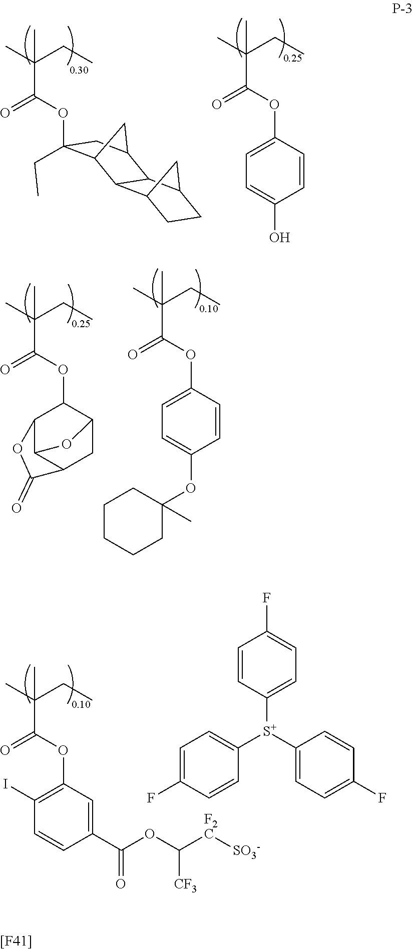

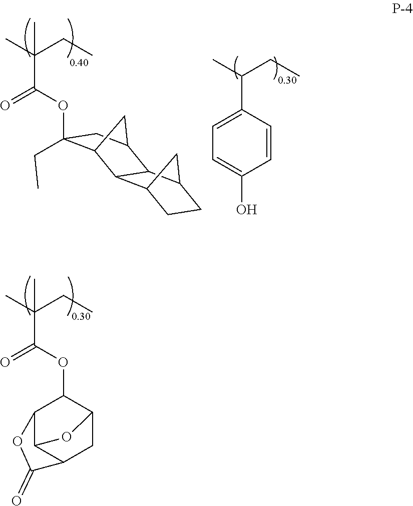

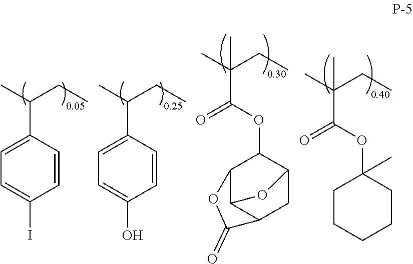

### Examples 1 to 15 and Comparative Examples 1 to 3

1. Preparation of Radiation-Sensitive Resin Composition

Each component was dissolved according to the compositions shown in Table 1 in a solvent in which 100 ppm of FC-4430 produced by 3M Japan Limited was dissolved as a surface active agent. The obtained solution was filtered through a membrane filter having a pore size of 0.2 μm, and a radiation-sensitive resin composition was prepared.

2. Evaluation of Sensitivity by EUV Exposure

Onto a silicon wafer having 12 inches, a composition for forming an underlayer film (“ARC66” produced by Brewer Science Inc.) was applied, with the use of a spin coater (“CLEAN TRACK ACT12” of Tokyo Electron Ltd.), and was then heated at 205° C. for 60 seconds; and thereby an underlayer film with an average thickness of 105 nm was formed. Onto this underlayer film, each of the radiation-sensitive resin compositions shown in Table 1 was applied with the use of the above spin coater, and was then subjected to the PB at 130° C. for 60 seconds. After that, the resultant coated film was cooled at 23° C. for 30 seconds, and thereby a resist film was formed which had an average thickness of 55 nm. The resist film was exposed with the use of an EUV scanner (ASML “NXE3300” (NA0.33, (0.9/0.6, quadrupole illumination, and mask of hole pattern having on-wafer size of pitch of 46 nm and bias of +20%). The resultant resist film was subjected to the PEB on a hot plate at 120° C. for 60 seconds, and then was developed with an aqueous solution of 2.38% by mass of tetramethylammonium hydroxide (TMAH) for 30 seconds; and a resist pattern was formed which had a hole with a size of 23 nm and a pitch of 46 nm. An amount of the exposure for forming the resist pattern having the hole with the size of 23 nm and the pitch of 46 nm was defined as an optimum exposure amount (Eop), and the optimum exposure amount was defined as sensitivity (mJ/cm²).

3. CDU Evaluation

A resist pattern having the hole with the size of 23 nm and the pitch of 46 nm was formed by application of the amount of exposure of Eop, which was determined as above, and through the same operations as in the above section 2. The formed resist pattern was observed from an upper portion of the pattern, with the use of a scanning electron microscope (“CG-5000” manufactured by Hitachi High-Technologies Corporation). The hole diameters were measured at 16 points in a range of the diameters of 500 nm, and an average value of the hole diameters was obtained. Such a measurement was repeatedly performed at 500 points in total at arbitrary points. A three-sigma value was determined from the distribution of the measured values, and the determined three-sigma value was used as an evaluation value (nm) of the CDU performance. The smaller the evaluation value of the CDU performance is, the smaller the fluctuation of the hole diameters in a long period is, and the more satisfactory the CDU performance is. The results are shown in Table 1.

4. Evaluation of Development Residue

A wafer having a resist film formed thereon was prepared by performing the same operations as in the above section 2 up to the operation of forming the resist film having the average thickness of 55 nm. Next, the whole surface of the resist film was exposed with the optimum exposure amount with the use of an EUV scanner, and then was subjected to the PEB on a hot plate at 120° C. for 60 seconds. Next, the resultant resist film was developed with the aqueous solution of 2.38% by mass of TMAH for 30 seconds, was then subjected to rinsing by pure water for 30 seconds, and was then dried. Thus, a wafer for the evaluation of the development residue was prepared. The wafer for the evaluation was observed with a defect inspection apparatus COMPLUS (manufactured by Applied Materials, Inc.); and the presence or absence of residue defects was confirmed with the use of a defect review SEM RS5500 (manufactured by Hitachi High-Technologies Corporation), and the number of residue defects was counted. According to the number of the counted residue defects, the development residue suppressing property was evaluated with the use of the following indices.
A: 5 or less
B: 6 to 10
C: 11 to 20
D: 21 or more

TABLE 1

| | Radiation-sensitive resin composition | | | | | | | |
|---|---|---|---|---|---|---|---|---|
| | | | | High | | | | |
| | Base | | Acid | fluorine- | | | | |
| | resin | PAG | diffusion | containing | | | | |
| | (Part | (Part | controller | resin | | Evaluation | | |
| | by | by | (Part by | (Part by | Solvent | Sensitivity | CDU | Development |
| | mass) | mass) | mass) | mass) | (Part by mass) | (mJ/cm²) | (nm) | residues |
| Example 1 | P-1 | PAG1 | Q-1 | F-1 | PGMEA/DAA | 15 | 2.4 | C |
| | (100) | (6.0) | (3.0) | (3.0) | (2,000/500) | | | |
| Example 2 | P-1 | PAG2 | Q-1 | F-1 | PGMEA/DAA | 15 | 2.4 | C |
| | (100) | (6.0) | (3.0) | (3.0) | (2,000/500) | | | |
| Example 3 | P-1 | PAG3 | Q-1 | F-1 | PGMEA/DAA | 14 | 2.4 | B |
| | (100) | (6.0) | (3.0) | (3.0) | (2,000/500) | | | |
| Example 4 | P-1 | PAG4 | Q-2 | F-1 | PGMEA/EL | 14 | 2.4 | B |
| | (100) | (6.0) | (3.0) | (3.0) | (2,000/500) | | | |
| Example 5 | P-1 | PAG3 | Q-3 | F-1 | PGMEA/EL | 14 | 2.4 | B |
| | (100) | (6.0) | (3.0) | (3.0) | (2,000/500) | | | |
| Example 6 | P-1 | PAG5 | Q-1 | F-1 | PGMEA/DAA | 13 | 2.4 | A |
| | (100) | (6.0) | (3.0) | (3.0) | (2,000/500) | | | |
| Example 7 | P-1 | PAG6 | Q-1 | F-1 | PGMEA/DAA | 13 | 2.4 | A |
| | (100) | (6.0) | (3.0) | (3.0) | (2,000/500) | | | |
| Example 8 | P-1 | PAG7 | Q-1 | F-1 | PGMEA/DAA | 12 | 2.4 | A |
| | (100) | (6.0) | (3.0) | (3.0) | (2,000/500) | | | |
| Example 9 | P-1 | PAG3 | Q-2 | F-1 | PGMEA/GBL | 14 | 2.4 | B |
| | (100) | (6.0) | (3.0) | (3.0) | (2,200/300) | | | |
| Example 10 | P-2 | PAG4 | Q-1 | F-1 | PGMEA/GBL | 14 | 2.4 | B |
| | (100) | (3.0) | (3.0) | (3.0) | (2,200/300) | | | |
| Example 11 | P-3 | PAG4 | Q-1 | F-1 | PGMEA/CHN/PGME | 14 | 2.2 | B |
| | (100) | (3.0) | (3.0) | (3.0) | (1,000/1,500/400) | | | |
| Example 12 | P-1 | PAG8 | Q-1 | F-1 | PGME/EL | 14 | 2.2 | B |
| | (100) | (5.0) | (3.0) | (3.0) | (2,000/500) | | | |
| Example 13 | P-1 | PAG4 | Q-4 | F-1 | PGME/EL | 14 | 2.2 | B |
| | (100) | (6.0) | (3.0) | (3.0) | (1,000/1,000) | | | |
| Example 14 | P-4 | PAG3 | Q-5 | F-1 | PGME/EL | 14 | 2.2 | B |
| | (100) | (6.0) | (3.0) | (3.0) | (500/2,000) | | | |
| Example 15 | P-2 | PAG3 | Q-2 | F-1 | PGME/EL | 13 | 2.2 | B |
| | (100) | (4.0) | (2.0) | (3.0) | (2,000/500) | | | |
| Comparative | P-1 | PAG9 | Q-1 | F-1 | PGME/EL | 16 | 2.4 | D |
| Example 1 | (100) | (6.0) | (3.0) | (3.0) | (2,000/500) | | | |
| Comparative | P-1 | PAG4 | Q-6 | F-1 | PGME/EL | 16 | 2.4 | D |
| Example 2 | (100) | (6.0) | (3.0) | (3.0) | (2,000/500) | | | |
| Comparative | P-5 | PAG1 | Q-1 | F-1 | PGME/EL | 16 | 2.2 | C |
| Example 3 | (100) | (6.0) | (3.0) | (3.0) | (2,000/500) | | | |

In Table 1, the details of the solvents are as follows.
PGMEA (propylene glycol monomethyl ether acetate)
GBL (γ-butyrolactone)
CHN (cyclohexanone)
PGME (propylene glycol monomethyl ether)
DAA (diacetone alcohol)
EL (ethyl lactate)

As a result of the evaluation of the resist patterns formed by the EUV exposure, the radiation-sensitive resin compositions of Examples 1 to 15 showed satisfactory sensitivity and CDU performance, and also showed less development residues. Among the compositions, the radiation-sensitive resin compositions of Examples 3 to 15, each of which included a radiation-sensitive onium cation in which the total number of fluoro groups and fluoroalkyl groups was 3 or more, as the specific cation structure [X], had each a development residue of 10 or less, and were evaluated as “A” or “B”. The effect of reducing the development residue was particularly excellent in the case where the total number of fluoro groups and fluoroalkyl groups in the specific cation structure [X] was 4 or more.

On the other hand, Comparative Examples 1 and 2 that included the structural unit (I) but did not include the specific cation structure [X] had lower sensitivity and more development residues than Examples 1 to 15. Comparative Example 3 which included the specific cation structure [X] but did not include the structural unit (I) showed lower sensitivity than Examples 1 to 15.

According to the radiation-sensitive resin composition and the method of forming the resist pattern formation method described above, the resist pattern can be formed that is satisfactory in the sensitivity to the exposure light and excellent in the CDU performance and the development residue suppressing property. Accordingly, these compositions can be suitably used in processes for manufacturing semiconductor devices which are anticipated to be further miniaturized in the future.

1: A radiation-sensitive composition comprising:
a polymer (A) comprising a structural unit represented by formula (i); and
at least one acid-generating compound comprising a radiation-sensitive onium cation structure and an organic anion structure, provided that the polymer (A) is excluded from the acid-generating compound,
wherein the radiation-sensitive composition satisfies at least one of conditions (K1) and (K2):
(K1) the polymer (A) comprises a fluorine-containing radiation-sensitive onium cation structure comprising two or more fluorine-containing groups each of which is a fluoroalkyl group or a fluoro group, provided that a fluoro group in the fluoroalkyl group is excluded from the fluoro group; and
(K2) the at least one acid-generating compound comprises a compound comprising the fluorine-containing radiation-sensitive onium cation structure, 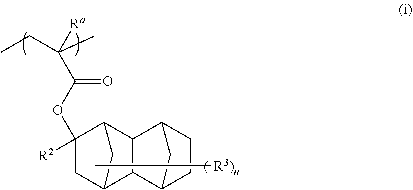
wherein: R^{a} is a hydrogen atom, a fluoro group, a methyl group or a trifluoromethyl group; R² is a monovalent hydrocarbon group having 1 to 20 carbon atoms; n is an integer of 0 to 16; when n is 1, R³ is a monovalent hydrocarbon group having 1 to 20 carbon atoms; and when n is 2 or more, a plurality of R³ each independently represent a monovalent hydrocarbon group having 1 to 20 carbon atoms, and optionally, at least two of the plurality of R³ taken together represent an alicyclic structure having 3 to 20 ring members together with a carbon atom or a carbon chain to which the at least two of the plurality of R³ bond.

2: The radiation-sensitive composition according to claim 1, wherein the fluorine-containing radiation-sensitive onium cation structure further comprises a sulfonium cation or an iodonium cation.

3: The radiation-sensitive composition according to claim 2, wherein
the fluorine-containing radiation-sensitive onium cation structure further comprises at least one aromatic ring Z each bonded to the sulfonium cation or the iodonium cation, and
the two or more fluorine-containing groups are bonded to one aromatic ring of the at least one aromatic ring Z or are bonded to two or more aromatic rings of the at least one aromatic ring Z.

4: The radiation-sensitive composition according to claim 1, further comprising, optionally, an additional polymer which is different from the polymer (A), wherein at least one of the polymer (A) and the additional polymer comprises a structural unit comprising an aromatic ring and a hydroxyl group bonded to the aromatic ring.

5: The radiation-sensitive composition according to claim 1, wherein the radiation-sensitive composition is suitable for forming a resist pattern through exposure to an extreme ultraviolet ray.

6: The radiation-sensitive composition according to claim 1, wherein the fluorine-containing radiation-sensitive onium cation structure is included in a compound different from the polymer (A).

7: The radiation-sensitive composition according to claim 1, wherein the polymer (A) comprises a structural unit comprising the fluorine-containing radiation-sensitive onium cation structure and an organic anion.

8: The radiation-sensitive composition according to claim 1, wherein the at least one acid-generating compound comprises:
a first acid-generating compound; and
a second acid-generating compound that generates an acid weaker than an acid generated by the first acid-generating compound through exposure.

9: A method of forming a resist pattern, the method comprising:
applying the radiation-sensitive composition according to claim 1 on a substrate to form a resist film;
exposing the resist film; and
developing the exposed resist film.

10: The method according to claim 9, wherein the resist film is exposed to an extreme ultraviolet ray.
